(19) United States
(12) Patent Application Publication
(10) Pub. No.: US 2024/0196740 A1
(43) Pub. Date: Jun. 13, 2024

(54) ORGANIC ELECTROLUMINESCENT MATERIAL AND DEVICE THEREOF

(71) Applicant: BEIJING SUMMER SPROUT TECHNOLOGY CO., LTD., Beijing (CN)

(72) Inventors: Feng Li, Beijing (CN); Zhen Wang, Beijing (CN); Hongbo Li, Beijing (CN); Yang Wang, Beijing (CN); Zheng Wang, Beijing (CN); Wei Cai, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 18/504,682

(22) Filed: Nov. 8, 2023

(30) Foreign Application Priority Data
Nov. 10, 2022 (CN) 202211403743.4
Mar. 22, 2023 (CN) 202310281822.0

(51) Int. Cl. H10K 85/60; C09K 11/06; H10K 85/30

(52) U.S. Cl. CPC H10K 85/654; C09K 11/06; H10K 85/342; H10K 85/6572; H10K 85/6574; H10K 50/12

(57) ABSTRACT

Provided is an organic electroluminescent device and use thereof. The organic electroluminescent device comprises a first emissive layer, the first emissive layer comprises a first compound and a first metal complex having a ligand L a having a specific structure. The maximum capacitance of the organic electroluminescent device is at least 0.35 nF lower than the maximum capacitance of an organic electroluminescent device whose first emissive layer comprises the first metal complex and GH0. The organic electroluminescent device has lower maximum capacitance, thereby improving the response time and the refresh frequency of an OLED display device at low grayscales. Further provided is a display assembly comprising the organic electroluminescent device.

### CROSS-REFERENCE TO RELATED APPLICATION(S)

This application claims priority to Chinese Patent Application No. 202211403743.4 filed on Nov. 10, 2022 and Chinese Patent Application No. 202310281822.0 filed on Mar. 22, 2023, the disclosure of which are incorporated herein by reference in their respective entireties.

### TECHNICAL FIELD

The present disclosure relates to organic electronic devices, for example, organic electroluminescent devices. In particular, the present disclosure relates to an organic electroluminescent device that includes a first emissive layer including a first metal complex having a ligand Lₐ having a specific structure and a first compound and that can reducing the maximum capacitance and a device assembly including the organic electroluminescent device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which includes an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may include multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may include one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

From the perspective of electronics, the display principle of the OLED is briefly explained as follows: under the action of an applied electric field greater than a certain threshold, holes and electrons are injected into an organic thin-film emissive layer sandwiched between the anode and the cathode, respectively, in the form of an electric current, the holes and electrons recombine to form excitons, and radiation recombination occurs to cause light emission. Since the organic emissive thin film has significant capacitance characteristics, the capacitance of the organic thin-film emissive layer is a key factor affecting the response time and refresh frequency of an OLED display device at a low grayscale.

In an OLED device, the movement, distribution, and accumulation of charges in the device can be analyzed by studying the C-V (capacitance-voltage) characteristics of the device. As shown in FIG. 1 which is an example curve graph of the capacitance-voltage (C-V) characteristic of a device, the kinetic study of the charge in the device can be roughly divided into the following four cases, depending on the applied bias voltages.
1) When the applied voltage V₀ is less than the initial voltage Vₜ, that is, V₀<Vₜ, the carriers (holes) cannot enter the interior of the device, and the device acts like an insulator connected between the cathode and the anode. Therefore, in this case, the capacitance of the device is a constant, and the capacitance in this case is referred to as the geometric capacitance C_{geo} of the device.
2) When the applied voltage V₀ is greater than the initial voltage Vₜ but is less than the voltage V_{Cmax}, that is, Vₜ<V₀<V_{Cmax}, the holes start to be injected into the interior of the device, and as the holes accumulate inside the device, the capacitance of the device gradually increases.
3) When the applied voltage V₀ continuously increases, the capacitance value of the device also continuously increases in this case until the applied voltage V₀ is equal to the voltage V_{Cmax} of the device, that is, V₀=V_{Cmax}, and the capacitance of the device reaches the maximum value Cₘₐₓ.
4) When the applied voltage V₀ is greater than the voltage V_{Cmax}, that is, V₀>V_{Cmax}, electrons start to be injected into the interior of the device, then the hole-electron recombination process occurs, and as the carriers accumulated in the device are consumed, the capacitance of the device gradually decreases.

As an organic semiconductor material, the compound GH0, with a structure:

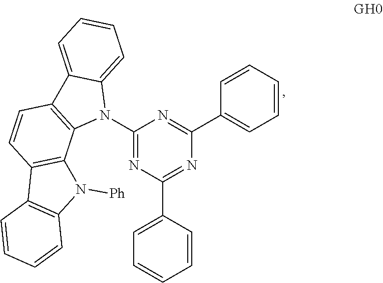 [SMILES: c1ccc(-c2nc(-c3ccccc3)nc(-n3c4ccccc4c4ccc5c6ccccc6n(-c6ccccc6)c5c43)n2)cc1]

has been widely used in OLED devices due to its superior optoelectronic properties, redox properties, stability, and the like. For example, existing published patent applications CN101511834A, WO2009136596A1, and CN111635436A disclose the application of the compound GH0 as a host material in OLED devices; and CN113527316A and CN114621199A disclose the application of the compound GH0 as an electron blocking material in OLED devices. However, the OLED devices using GH0 generally have a large capacitance, limiting their further application.

The magnitude of the capacitance of the device is affected by the injection and transport of charges from the materials in the organic thin-film emissive layer. Some studies have shown that the capacitance of the device can be reduced by reducing the injection of holes. However, such a method may affect the charge balance inside the device, thereby affecting the efficiency and lifetime of the device. For OLED devices, the emissive layer is an important medium for the combination of holes and electrons to form excitons and ultimately emit light, and the charge balance inside the emissive layer has an important impact on the formation of excitons and the emission efficiency. At present, although organometallic complex phosphorescent OLED devices have already had high efficiency, long lifetime, and other excellent device performance, in order to bring a better visual experience, how to efficiently improve the refresh frequency of OLED devices is one of the problems that need to be solved. The present disclosure aims to study how to reduce the capacitance of the device. By selecting the combination of materials in the emissive layer in the organic electroluminescent device, the electron and hole balance of the device is improved, and the capacitance of the device is reduced, thereby improving the response time and the refresh frequency of the device at low grayscales.

### SUMMARY

The present disclosure aims to provide an organic electroluminescent device to solve at least part of the above problems. The organic electroluminescent device includes a first emissive layer including a first metal complex having a ligand Lₐ having a specific structure and a first compound. The maximum capacitance of the organic electroluminescent device is at least 0.35 nF lower than the maximum capacitance of an organic electroluminescent device whose emissive layer includes the first metal complex and GH0. The organic electroluminescent device has lower maximum capacitance, thereby improving the response time and the refresh frequency of an OLED display device at low grayscales.

According to an embodiment of the present disclosure, an organic electroluminescent device is disclosed. The organic electroluminescent device includes a cathode, an anode, and an organic layer disposed between the cathode and the anode;
the organic layer includes a first emissive layer, and the first emissive layer includes a first compound and a first metal complex;
the capacitance characteristic of the organic electroluminescent device satisfies the following conditions:
at 500 Hz, the maximum value of the capacitance of the organic electroluminescent device is Cₘₐₓ; and
at 500 Hz, the maximum value of the capacitance of an organic electroluminescent device using the compound GH0 to replace the first compound in the first emissive layer is Cₘₐₓ₀;

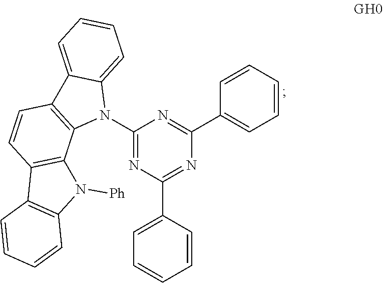 [SMILES: c1ccc(-c2nc(-c3ccccc3)nc(-n3c4ccccc4c4ccc5c6ccccc6n(-c6ccccc6)c5c43)n2)cc1]

wherein Cₘₐₓ−Cₘₐₓ₀≤−0.35 nF;
the first metal complex has a general formula of M(Lₐ)ₘ(L_{b})ₙ(L_{c})_{q};
M is selected from a metal with a relative atomic mass greater than 40;
Lₐ, L_{b}, and L_{c} are a first ligand, a second ligand, and a third ligand coordinated to the metal M, respectively, and Lₐ, L_{b}, and L_{c} are identical or different; wherein Lₐ, L_{b}, and L_{c} can be optionally joined to form a tetradentate ligand or a multidentate ligand;
m is selected from 1, 2 or 3, n is selected from 0, 1 or 2, q is selected from 0, 1 or 2, and m+n+q equals an oxidation state of the metal M; when m is greater than or equal to 2, a plurality of Lₐ are identical or different; when n is equal to 2, two L_{b} are identical or different; when q is equal to 2, two L_{c} are identical or different;
the ligand Lₐ has a structure represented by Formula 1:

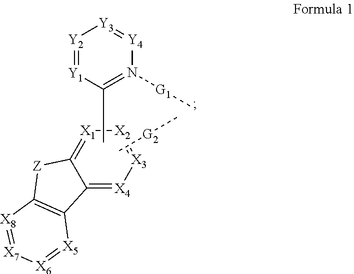

wherein
Z is selected from the group consisting of O, S, Se, NR, CRR, SiRR, and GeRR; when two R are present, the two R are identical or different;
G₁ and G₂ are, at each occurrence identically or differently, selected from a single bond, O or S;
two of X₁ to X₄ are selected from C, one of the two C is joined to the N-containing ring shown in Formula 1, the other one of the two C is joined to the metal via G₂, and the remaining two of X₁ to X₄ are each independently selected from CRₓ;
X₅ to X₈ are, at each occurrence identically or differently, selected from CRₓ;

Y₁ to Y₄ are, at each occurrence identically or differently, selected from CR_{y} or N;

R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R, Rₓ, and R_{y} can be optionally joined to form a ring; and
L_{b} and L_{c} are, at each occurrence identically or differently, selected from a monoanionic multidentate ligand.

According to another embodiment of the present disclosure, a display assembly is further disclosed. The display assembly includes the organic electroluminescent device described in the preceding embodiment.

In the present disclosure, the organic electroluminescent device uses in the emissive layer the material combination of a first metal complex having a ligand Lₐ having a specific structure and a first compound. The maximum capacitance of the organic electroluminescent device is at least 0.35 nF lower than the maximum capacitance of an organic electroluminescent device that includes the first metal complex and GH0. The organic electroluminescent device has lower maximum capacitance, thereby improving the response time and the refresh frequency of an OLED display device at low grayscales.

### BRIEF DESCRIPTION OF DRAWINGS

FIG. 1 is an example curve graph of the capacitance-voltage (C-V) characteristic of the device.

FIG. 2 is a schematic diagram of an organic electroluminescent device disclosed by the present disclosure.

FIG. 3 is a schematic diagram of another organic electroluminescent device disclosed by the present disclosure.

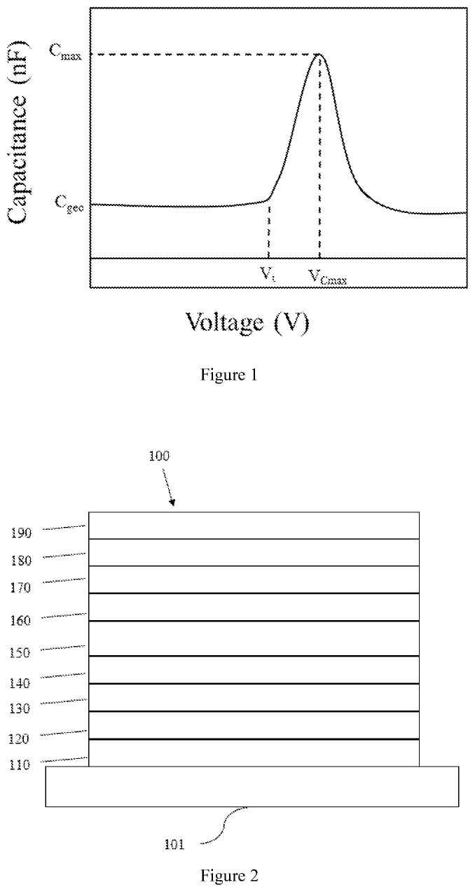

### DETAILED DESCRIPTION

OLEDs can be fabricated on various types of substrates such as glass, plastic, and metal foil. FIG. 2 schematically shows an organic light-emitting device 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

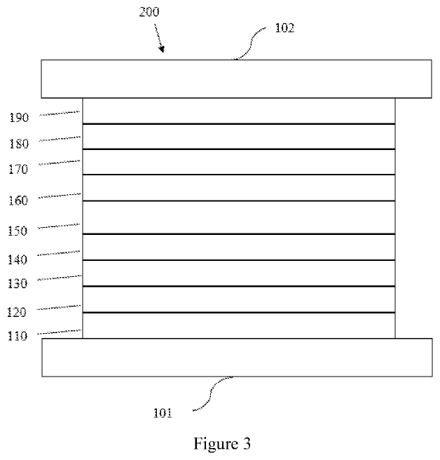

An OLED can be encapsulated by a barrier layer. FIG. 3 schematically shows an organic light emitting device 200 without limitation. FIG. 3 differs from FIG. 2 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

As used herein, “emission area” means the area of an organic electroluminescent device in the direction perpendicular to the emissive surface where the anode is in direct contact with the organic layer and at the same time the organic layer is in direct contact with the cathode. Herein, the emission area in examples and comparative examples is 0.04 cm².

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butylmethylgermanylmethyl, triethylgermanylmethyl, triethylgermanylethyl, triisopropylgermanylmethyl, triisopropylgermanylethyl, trimethylsilylmethyl, trimethylsilylethyl, and trimethylsilylisopropyl, triisopropylsilylmethyl, triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl -1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cycl op entyl oxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthyl ethyl, 2-alpha-naphthyl ethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkyl silyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropyl silyl, tri-t-butyl silyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with an aryl group. Arylsilyl groups may be those having 6 to 30 carbon atoms, preferably those having 8 to 20 carbon atoms. Examples of aryl silyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, amino, acyl, carbonyl, a carboxylic acid group, an ester group, sulfinyl, sulfonyl, and phosphino may be substituted with one or more moieties selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl having 6 to 20 carbon atoms, unsubstituted alkylgermanyl having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen can also be replaced by their other stable isotopes. The replacement by other stable isotopes in the compounds may be preferred due to its enhancements of device efficiency and stability.

In the compounds mentioned in the present disclosure, multiple substitution refers to a range that includes a di-substitution, up to the maximum available substitution. When substitution in the compounds mentioned in the present disclosure represents multiple substitution (including di-, tri-, and tetra-substitutions, etc.), that means the substituent may exist at a plurality of available substitution positions on its linking structure, the substituents present at a plurality of available substitution positions may be the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

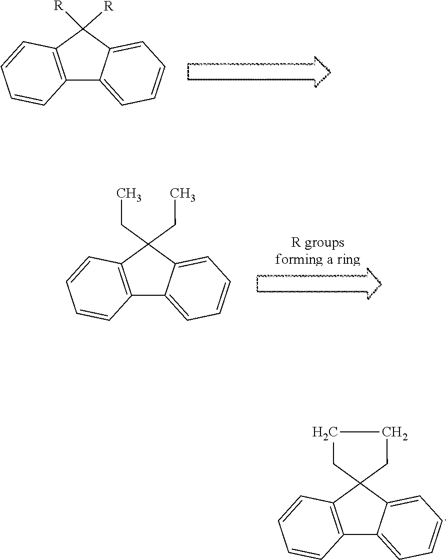

The expression that adjacent substituents can be optionally joined to form a ring is also intended to mean that two substituents bonded to carbon atoms which are directly bonded to each other are joined to each other via a chemical bond to form a ring, which can be exemplified by the following formula:

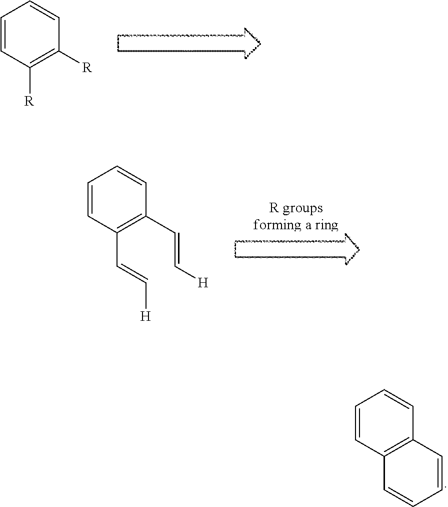

The expression that adjacent substituents can be optionally joined to form a ring is also intended to mean that two substituents bonded to a further distant carbon atom are joined to each other via a chemical bond to form a ring, which can be exemplified by the following formula:

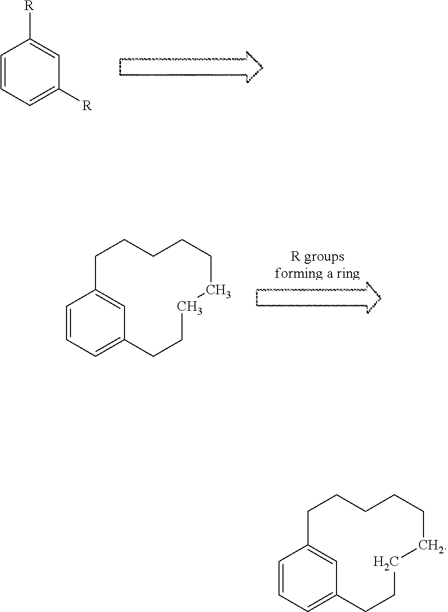

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

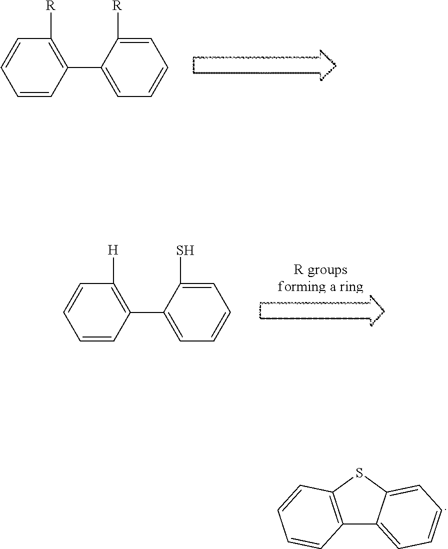

According to an embodiment of the present disclosure, an organic electroluminescent device is disclosed. The organic electroluminescent device includes a cathode, an anode, and an organic layer disposed between the cathode and the anode;
the organic layer includes a first emissive layer, and the first emissive layer includes a first compound and a first metal complex;
the capacitance characteristic of the organic electroluminescent device satisfies the following conditions:
at 500 Hz, the maximum value of the capacitance of the organic electroluminescent device is Cₘₐₓ; and
at 500 Hz, the maximum value of the capacitance of an organic electroluminescent device using the compound GH0 to replace the first compound in the first emissive layer is Cₘₐₓ₀;

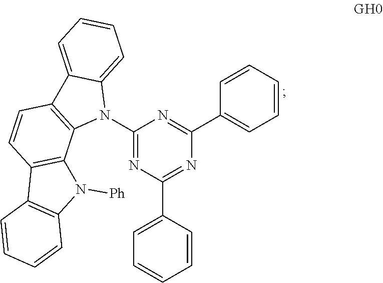 [SMILES: c1ccc(-c2nc(-c3ccccc3)nc(-n3c4ccccc4c4ccc5c6ccccc6n(-c6ccccc6)c5c43)n2)cc1]

wherein Cₘₐₓ−Cₘₐₓ₀≤−0.35 nF;
the first metal complex has a general formula of M(Lₐ)ₘ(L_{b})ₙ(L_{c})_{q};
M is selected from a metal with a relative atomic mass greater than 40;
Lₐ, L_{b}, and L_{c} are a first ligand, a second ligand, and a third ligand coordinated to the metal M, respectively, and Lₐ, L_{b}, and L_{c} are identical or different; wherein Lₐ, L_{b}, and L_{c} can be optionally joined to form a tetradentate ligand or a multidentate ligand;
m is selected from 1, 2 or 3, n is selected from 0, 1 or 2, q is selected from 0, 1 or 2, and m+n+q equals an oxidation state of the metal M; when m is greater than or equal to 2, a plurality of Lₐ are identical or different; when n is equal to 2, two L_{b} are identical or different; when q is equal to 2, two L_{c} are identical or different;
the ligand Lₐ has a structure represented by Formula 1:

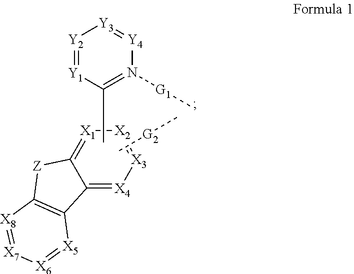

wherein
Z is selected from the group consisting of O, S, Se, NR, CRR, SiRR, and GeRR; when two R are present, the two R are identical or different;
G₁ and G₂ are, at each occurrence identically or differently, selected from a single bond, O or S;
two of X₁ to X₄ are selected from C, one of the two C is joined to the N-containing ring shown in Formula 1, the other one of the two C is joined to the metal via G₂, and the remaining two of X₁ to X₄ are each independently selected from CRₓ;
X₅ to X₈ are, at each occurrence identically or differently, selected from CRₓ;
Y₁ to Y₄ are, at each occurrence identically or differently, selected from CR_{y} or N;
R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R, Rₓ, and R_{y} can be optionally joined to form a ring; and
L_{b} and L_{c} are, at each occurrence identically or differently, selected from a monoanionic multidentate ligand.

Herein, “at 500 Hz, the maximum value of the capacitance of an organic electroluminescent device using the compound GH0 to replace the first compound in the first emissive layer is Cₘₐₓ₀” is intended to mean: for any organic electroluminescent device Y_{A} claimed to be protected by the present disclosure that has a first emissive layer including a first compound and a first metal complex, when a voltage (V₀) that is equal to a voltage V_{Cmax} is applied to the organic electroluminescent device Y_{A} at 500 Hz, the maximum capacitance of the device measured is Cₘₐₓ; for another organic electroluminescent device Y that differs from the organic electroluminescent device Y_{A} only in that the first compound is replaced with the compound GH0, when a voltage (V₀) that is equal to a voltage V_{Cmax0} applied to the organic electroluminescent device Y at 500 Hz, the maximum capacitance of the device measured is Cₘₐₓ₀. The difference of Cₘₐₓ−Cₘₐₓ₀ herein is the difference between the maximum capacitance of the organic electroluminescent device Y_{A} and the maximum capacitance of the organic electroluminescent device Y. It is to be noted that the maximum value Cₘₐₓ of the capacitance of the organic electroluminescent device Y_{A}, the maximum value Cₘₐₓ₀ of the capacitance of the organic electroluminescent device Y, and Cₘₐₓ−Cₘₐₓ₀≤−0.35 nF are all values measured under the following condition: the emissive areas of the organic electroluminescent device YA and the organic electroluminescent device Y are both 0.04 cm². It is to be understood by those skilled in the art that if the emissive area of the device changes, the corresponding maximum capacitance Cₘₐₓ₀ and Cₘₐₓ and Cₘₐₓ−Cₘₐₓ₀ naturally change in accordance with the law of “the maximum capacitance per unit of emissive area of the device=maximum capacitance/emissive area”.

Herein, the expression that “adjacent substituents R, Rₓ, and R_{y} can be optionally joined to form a ring” is intended to mean that any one or more of groups of adjacent substituents, such as two substituents R, two substituents Rₓ, two substituents R_{y}, and substituents R and Rₓ, can be joined to form a ring. Obviously, it is also possible that these substituents are not joined to form a ring.

According to an embodiment of the present disclosure, the lowest unoccupied molecular orbital energy level E_{LUMO} of the first compound is less than or equal to −2.75 eV.

According to an embodiment of the present disclosure, the lowest unoccupied molecular orbital energy level E_{LUMO} of the first compound is less than or equal to −2.80 eV.

According to an embodiment of the present disclosure, at 500 Hz, Cₘₐₓ−Cₘₐₓ₀≤−0.45 nF.

According to an embodiment of the present disclosure, at 500 Hz, Cₘₐₓ−Cₘₐₓ₀≤−0.55 nF.

According to an embodiment of the present disclosure, at 500 Hz, 2.5 nF≤Cₘₐₓ₀≤6.0 nF.

According to an embodiment of the present disclosure, at 500 Hz, for the maximum value of the capacitance of the organic electroluminescent device, 0.5 nF≤Cₘₐₓ≤5.5 nF.

According to an embodiment of the present disclosure, at 500 Hz, for the maximum value of the capacitance of the organic electroluminescent device, 1.0 nF≤Cₘₐₓ≤4.0 nF.

According to an embodiment of the present disclosure, at 500 Hz, for the maximum value of the capacitance of the organic electroluminescent device, 1.0 nF≤Cₘₐₓ≤3.0 nF.

According to an embodiment of the present disclosure, at 500 Hz, the initial voltage of the organic electroluminescent device is Vₜ and satisfies: −4.0 V≤Vₜ≤5.0 V.

According to an embodiment of the present disclosure, at 500 Hz, the initial voltage of the organic electroluminescent device is Vₜ and satisfies: −3.0 V≤Vₜ≤3.0 V.

According to an embodiment of the present disclosure, at 500 Hz, when the capacitance of the organic electroluminescent device reaches the maximum value Cₘₐₓ, the corresponding voltage is V_{Cmax} and satisfies: 1.0 V≤V_{Cmax}≤6.0 V.

According to an embodiment of the present disclosure, at 500 Hz, when the capacitance of the organic electroluminescent device reaches the maximum value Cₘₐₓ, the corresponding voltage is V_{Cmax} and satisfies: 1.5 V≤V_{Cmax}≤5.0 V.

According to an embodiment of the present disclosure, at 500 Hz, when the capacitance of the organic electroluminescent device reaches the maximum value Cmax, the corresponding voltage is V_{Cmax} and satisfies: 1.5 V≤V_{Cmax}≤4.0 V.

According to an embodiment of the present disclosure, the first emissive layer further includes a second compound.

According to an embodiment of the present disclosure, the second compound includes at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof

According to an embodiment of the present disclosure, the second compound includes at least one chemical group selected from the group consisting of: benzene, carbazole, indolocarbazole, fluorene, silafluorene, and combinations thereof.

According to an embodiment of the present disclosure, the first metal complex is doped in the first compound and the second compound, and the weight of the first metal complex accounts for 1% to 30% of the total weight of the first emissive layer.

According to an embodiment of the present disclosure, the first metal complex is doped in the first compound and the second compound, and the weight of the first metal complex accounts for 3% to 13% of the total weight of the first emissive layer.

According to an embodiment of the present disclosure, the organic electroluminescent device is a top-emitting device.

According to an embodiment of the present disclosure, the organic electroluminescent device is a bottom-emitting device.

According to an embodiment of the present disclosure, the organic electroluminescent device is a tandem device.

According to an embodiment of the present disclosure, the organic electroluminescent device is a single-layer device.

According to an embodiment of the present disclosure, the organic electroluminescent device emits green light. According to an embodiment of the present disclosure, the organic electroluminescent device emits yellow light.

According to an embodiment of the present disclosure, the organic electroluminescent device emits white light.

According to an embodiment of the present disclosure, the first compound has a structure as show in Formula 2:

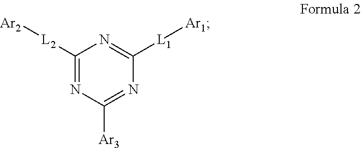

wherein
L₁ and L₂ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms or combinations thereof;
Ar₁ and Ar₂ are, at each occurrence identically or differently, selected from substituted or unsubstituted aryl having 6 to 30 carbon atoms, substituted or unsubstituted heteroaryl having 3 to 30 carbon atoms or combinations thereof;
Ar₃ a has a structure represented by Formula A:

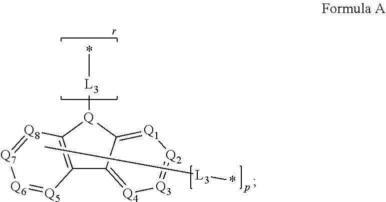

wherein
Q is, at each occurrence identically or differently, selected from the group consisting of O, S, Se, N, NR_{Q}, CR_{Q}R_{Q}, SiR_{Q}R_{Q}, GeR_{Q}R_{Q}, R_{Q}C═CR_{Q}, and C═CR_{Q}; when two R_{Q} are present, the two R_{Q} can be identical or different;
L₃ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
p is 0 or 1, r is 0 or 1, and p +q =1;
when p is 0 and r is 1, Q is selected from N or C═CR_{Q}; Q₁ to Q₈ are, at each occurrence identically or differently, selected from CR q or N; when Q is selected from N and L₃ is a single bond, adjacent substituents R_{q} cannot be joined to form an indole ring or a benzoindole ring; when Q is selected from C═CR_{Q}, the C which is not directly joined to R_{Q} is joined to L₃ in Formula A;
when p is 1 and r is 0, Q is selected from the group consisting of O, S, Se, NR_{Q}, CR_{Q}R_{Q}, SiR_{Q}R_{Q}, GeR_{Q}R, and R_{Q}C═CR_{Q}; Q₁ to Q₈ are, at each occurrence identically or differently, selected from C, CR_{q} or N; one of Q₁ to Q₈ is selected from C, and the C is joined to L₃ in Formula A;
R_{Q} and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents a position where Formula A is joined to Formula 2; and
adjacent substituents R_{Q} and R_{q} can be optionally joined to form a ring. Herein, when p is 0 and r is 1, Formula A has a structure represented by Formula A-1:

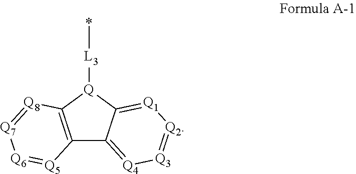

In Formula A-1, when Q is selected from N and L₃ is a single bond, Formula A has the following structure:

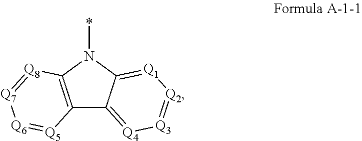

and adjacent substituents R_{q} cannot be joined to form an indole ring or a benzoindole ring; in Formula A-1, when Q is selected from C═CR_{Q}, wherein C in C═CR_{Q} is joined to L₃ in Formula A, Formula A has the following structure:

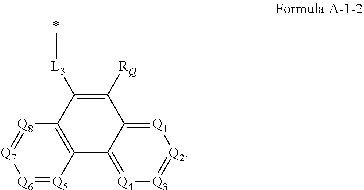

Herein, when p is 1 and r is 0, Formula A has a structure represented by Formula A-2:

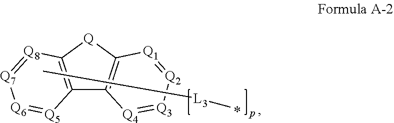

wherein any one of Q₁ to Q₈ is selected from C, and the C is joined to L₃ in Formula A.

Herein, the expression that “adjacent substituents R_{Q} and R_{q} can be optionally joined to form a ring” is intended to mean that any one or more of groups of adjacent substituents, such as two substituents R_{Q}, two substituents R_{q}, and substituents R_{Q} and R_{q}, can be joined to form a ring. Obviously, it is also possible that these substituents are not joined to form a ring.

According to an embodiment of the present disclosure, Q₁ to Q₈ are, at each occurrence identically or differently, selected from C or CR_{q}.

According to an embodiment of the present disclosure, Ar₁ and Ar₂ are, at each occurrence identically or differently, selected from substituted or unsubstituted aryl having 6 to 20 carbon atoms, substituted or unsubstituted heteroaryl having 3 to 20 carbon atoms or combinations thereof

According to an embodiment of the present disclosure, Ar₁ and Ar₂ are, at each occurrence identically or differently, selected from the group consisting of: substituted or unsubstituted phenyl, substituted or unsubstituted naphthyl, substituted or unsubstituted phenanthryl, substituted or unsubstituted biphenyl, substituted or unsubstituted terphenyl, substituted or unsubstituted triphenylenyl, substituted or unsubstituted fluorenyl, substituted or unsubstituted carbazolyl, substituted or unsubstituted dibenzofuryl, substituted or unsubstituted dibenzothienyl, and combinations thereof.

According to an embodiment of the present disclosure, the first compound has a structure represented by Formula 2-1:

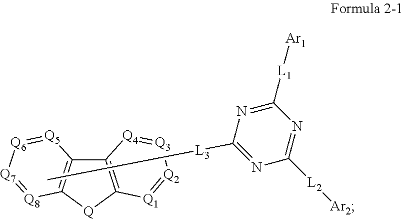

wherein
Q is, at each occurrence identically or differently, selected from the group consisting of O, S, and Se;
Q₁ to Q₈ are, at each occurrence identically or differently, selected from C, CR_{q} or N, and one of Q₁ to Q₈ is C and is joined to L₃;
L₁ to L₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms or combinations thereof;
Ar₁ and Ar₂ are, at each occurrence identically or differently, selected from substituted or unsubstituted aryl having 6 to 30 carbon atoms, substituted or unsubstituted heteroaryl having 3 to 30 carbon atoms or combinations thereof;
R_{q} is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{q} can be optionally joined to form a ring.

Herein, the expression that “adjacent substituents R_{q} can be optionally joined to form a ring” is intended to mean that any one or more of groups of adjacent substituents, such as any two substituents R_{q}, can be joined to form a ring. Obviously, it is also possible that these substituents are not joined to form a ring.

According to an embodiment of the present disclosure, the first compound has a structure represented by Formula 2-1, at least one of Q₁ to Q₈ is CR_{q}, and the R_{q} is selected from substituted or unsubstituted aryl having 6 to 30 carbon atoms, substituted or unsubstituted heteroaryl having 3 to 30 carbon atoms or combinations thereof.

According to an embodiment of the present disclosure, the first compound has a structure represented by Formula 2-1, at least one of Q₁ to Q₈ is CR_{q}, and the R_{q} is selected from substituted or unsubstituted aryl having 6 to 30 carbon atoms.

According to an embodiment of the present disclosure, the first compound has a structure represented by Formula 2-1, Q₄ is selected from C and is joined to L₃; Q₈ is CR_{q}, and the R_{q} is substituted or unsubstituted aryl having 6 to 30 carbon atoms.

According to an embodiment of the present disclosure, the first compound has a structure represented by Formula 2-1, Q₂ is selected from C and is joined to L₃; Q₅ is CR_{q}, and the R_{q} is substituted or unsubstituted aryl having 6 to 30 carbon atoms.

According to an embodiment of the present disclosure, the first compound has a structure represented by Formula 2-1, wherein Ar₁ and/or Ar₂ have a structure represented by Formula B:

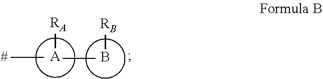

wherein the ring A and the ring B are, at each occurrence identically or differently, selected from an aromatic ring having 6 to 30 carbon atoms, a heteroaromatic ring having 3 to 30 carbon atoms or combinations thereof;

R_{A} and R_{B} represent, at each occurrence identically or differently, mono-substitution, multiple substitutions or non-substitution;

R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one of R_{A} and R_{B} is selected from a cyano group;
adjacent substituents R_{A} and R_{B} can be optionally joined to form a ring; and
“#” represents a position where Formula B is joined to Formula 2-1.

In this embodiment, the expression that “adjacent substituents R_{A} and R_{B} can be optionally joined to form a ring” is intended to mean that any one or more of groups of adjacent substituents, such as two substituents R_{A}, two substituents R_{B}, and substituents R_{A} and R_{B}, can be joined to form a ring. Obviously, it is also possible that these substituents are not joined to form a ring.

According to an embodiment of the present disclosure, the first compound has a structure represented by Formula 2-1-1:

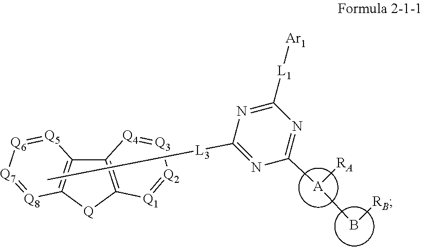

wherein
Q is, at each occurrence identically or differently, selected from the group consisting of O, S, and Se;
Q₁ to Q₈ are, at each occurrence identically or differently, selected from C, CR_{q} or N, and one of Q₁ to Q₈ is C and is joined to L₃;
L₁ and L₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms or combinations thereof;
Ar₁ is, at each occurrence identically or differently, selected from substituted or unsubstituted aryl having 6 to 30 carbon atoms, substituted or unsubstituted heteroaryl having 3 to 30 carbon atoms or combinations thereof;
the ring A and the ring B are, at each occurrence identically or differently, selected from an aromatic ring having 6 to 30 carbon atoms, a heteroaromatic ring having 3 to 30 carbon atoms or combinations thereof;
R_{A} and R_{B} represent, at each occurrence identically or differently, mono-substitution, multiple substitutions or non-substitution;
R_{q}, R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one of R_{A} and R_{B} is selected from a cyano group; and adjacent substituents R_{q}, R_{A}, and R_{B} can be optionally joined to form a ring.

Herein, the expression that “adjacent substituents R_{q}, R_{A}, and R_{B} can be optionally joined to form a ring” is intended to mean that any one or more of groups of adjacent substituents, such as two substituents R_{q}, two substituents R_{A}, two substituents R_{B}, and substituents R_{A} and R_{B}, can be joined to form a ring. Obviously, it is also possible that these substituents are not joined to form a ring.

According to an embodiment of the present disclosure, at least one R_{B} is selected from a cyano group.

According to an embodiment of the present disclosure, the first compound has a structure represented by Formula 2-1-1, Q₂ is selected from C and is joined to L₃; Q₅ is CR_{q}, and R_{q} is substituted or unsubstituted aryl having 6 to 30 carbon atoms.

According to an embodiment of the present disclosure, the first compound has a structure represented by Formula 2-2:

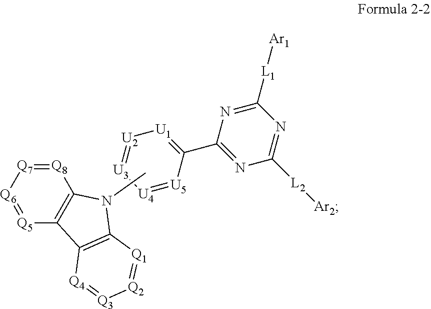

wherein
Q₁ to Q₈ are, at each occurrence identically or differently, selected from CR_{q} or N;
U₁ to U₅ are, at each occurrence identically or differently, selected from C, CRₐ or N, and one of U₁ to U₅ is C and is joined to a structure

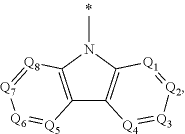

wherein “*” represents a joining position;

L₁ and L₂ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms or combinations thereof;
Ar₁ and Ar₂ are, at each occurrence identically or differently, selected from substituted or unsubstituted aryl having 6 to 30 carbon atoms, substituted or unsubstituted heteroaryl having 3 to 30 carbon atoms or combinations thereof;
R_{q} and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{q} and Rᵤ can be optionally joined to form a ring.

Herein, the expression that “adjacent substituents R_{q} and Rᵤ can be optionally joined to form a ring” is intended to mean that any one or more of groups of adjacent substituents, such as two substituents R_{q}, two substituents R_{q}, and substituents R_{q} and Rᵤ, can be joined to form a ring. Obviously, it is also possible that these substituents are not joined to form a ring.

According to an embodiment of the present disclosure, the first compound has a structure represented by Formula 2-2, at least one of U₁ to U₅ is selected from CRᵤ, and the Rᵤ is selected from substituted or unsubstituted aryl having 6 to 30 carbon atoms, substituted or unsubstituted heteroaryl having 3 to 30 carbon atoms or combinations thereof.

According to an embodiment of the present disclosure, the first compound has a structure represented by Formula 2-2, at least one of U₁ to U₅ is selected from CRᵤ, and the Rᵤ is selected from substituted or unsubstituted aryl having 6 to 20 carbon atoms, substituted or unsubstituted heteroaryl having 3 to 20 carbon atoms or combinations thereof.

According to an embodiment of the present disclosure, the first compound has a structure represented by Formula 2-2, U₃ is selected from CRᵤ, and the Rᵤ is selected from substituted or unsubstituted aryl having 6 to 20 carbon atoms, substituted or unsubstituted heteroaryl having 3 to 20 carbon atoms or combinations thereof.

According to an embodiment of the present disclosure, the first compound has a structure represented by Formula 2-2, U₃ is selected from CRᵤ, and the Rᵤ is selected from substituted or unsubstituted phenyl, substituted or unsubstituted naphthyl, substituted or unsubstituted phenanthryl, substituted or unsubstituted biphenyl, substituted or unsubstituted terphenyl, substituted or unsubstituted triphenylenyl, substituted or unsubstituted fluorenyl, substituted or unsubstituted carbazolyl, substituted or unsubstituted dibenzofuryl, substituted or unsubstituted dibenzothienyl or combinations thereof.

According to an embodiment of the present disclosure, the first compound has a structure represented by Formula 2-2-1:

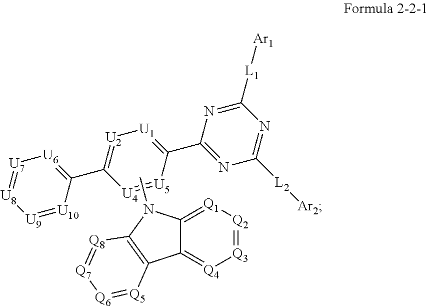

wherein Q₁ to Q₈ are, at each occurrence identically or differently, selected from CR_{q} or N;
U₁, U₂, U₄, and U₅ are, at each occurrence identically or differently, selected from C, CRᵤ or N, and one of U₁, U₂, U₄, and U₅ is C and is joined to a structure

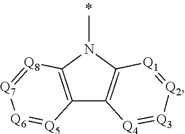

U₆ to U₁₀ are, at each occurrence identically or differently, selected from CRᵤ or N;
L₁ and L₂ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms or combinations thereof;

Ar₁ and Ar₂ are, at each occurrence identically or differently, selected from substituted or unsubstituted aryl having 6 to 30 carbon atoms, substituted or unsubstituted heteroaryl having 3 to 30 carbon atoms or combinations thereof;
R_{q} and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{q} and Rᵤ can be optionally joined to form a ring.

According to an embodiment of the present disclosure, the first compound includes, but is not limited to, the group consisting of Compound A-1 to Compound A-40, wherein for the specific structures of Compound A-1 to Compound A-40, reference is made to claim 15.

According to an embodiment of the present disclosure, hydrogens in Compound A-1 to Compound A-40 can be partially or fully substituted with deuterium.

According to an embodiment of the present disclosure, the metal M is, at each occurrence identically or differently, selected from the group consisting of Cu, Ag, Au, Ru, Rh, Pd, Os, Ir, and Pt.

According to an embodiment of the present disclosure, the metal M is, at each occurrence identically or differently, selected from Pt or Ir.

According to an embodiment of the present disclosure, Lₐ is, at each occurrence identically or differently, selected from the group consisting of structures represented by Formula 1-1 to Formula 1-4:

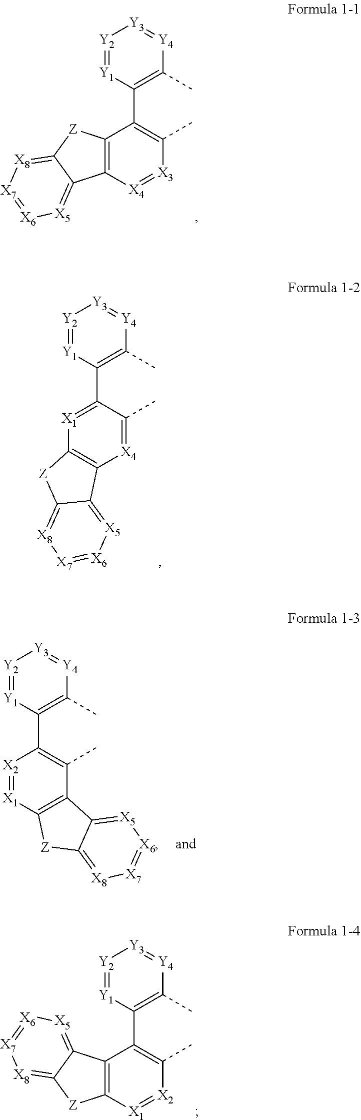

wherein
Z is selected from the group consisting of O, S, Se, NR, CRR, SiRR, and GeRR; when two R are present, the two R are identical or different;
X₁ to X₈ are, at each occurrence identically or differently, selected from CRₓ;
Y₁ to Y₄ are, at each occurrence identically or differently, selected from CR_{y} or N;
R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R, Rₓ, and R_{y} can be optionally joined to form a ring.

Herein, the expression that “adjacent substituents R, Rₓ, and R_{y} can be optionally joined to form a ring” is intended to mean that any one or more of groups of adjacent substituents, such as two substituents R, two substituents Rₓ, two substituents R_{y}, and substituents R and Rₓ, can be joined to form a ring. Obviously, it is also possible that these substituents are not joined to form a ring.

According to an embodiment of the present disclosure, L_{b} and L_{c} are, at each occurrence identically or differently, selected from a structure as shown in any one of the group consisting of the following:

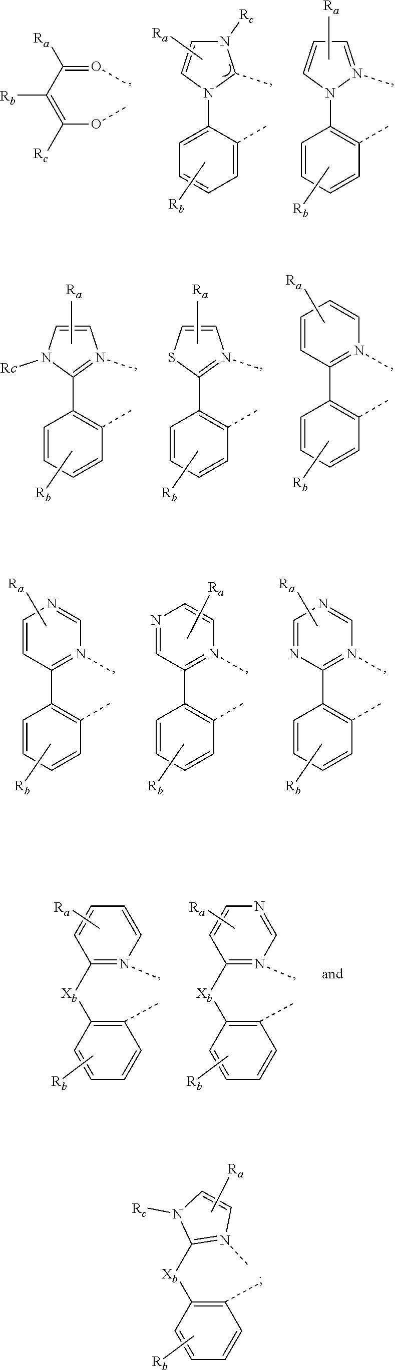

wherein
X_{b} is, at each occurrence identically or differently, selected from the group consisting of: O, S, Se, NR_{N1}, and CR_{C1}R_{C2};
Rₐ and R_{b} represent, at each occurrence identically or differently, mono-substitution, multiple substitutions or non-substitution;
Rₐ, R_{b}, R_{c}, R_{N1}, R_{N2}, R_{C1} and R_{C2} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents Rₐ, R_{b}, R_{c}, R_{N1}, R_{C1}, and R_{C2} can be optionally joined to form a ring.

Herein, the expression that “adjacent substituents Rₐ, R_{b}, R_{c}, R_{N1}, R_{C1}, and R_{C2} can be optionally joined to form a ring” is intended to mean that any one or more of groups of adjacent substituents, such as two substituents Rₐ, two substituents R_{b}, substituents Rₐ and R_{b}, substituents Rₐ and R_{c}, substituents R_{b} and R_{c}, substituents Rₐ and R_{N1}, substituents R_{b} and R_{N1}, substituents Rₐ and R_{C1}, substituents Rₐ and R_{C2}, substituents R_{b} and R_{C1}, substituents R_{b} and R_{C2}, and substituents R_{C1} and R_{C2}, can be joined to form a ring. Obviously, it is also possible that these substituents are not joined to form a ring. For example, adjacent substituents Rₐ and R_{b} in

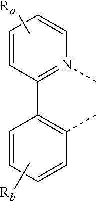

can be optionally joined to form a ring, and when Rₐ is optionally joined to form a ring,

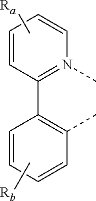

may form a structure of

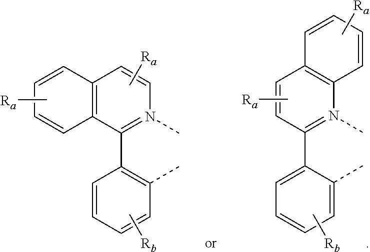

According to an embodiment of the present disclosure, the metal complex has a structure represented by Formula 3:

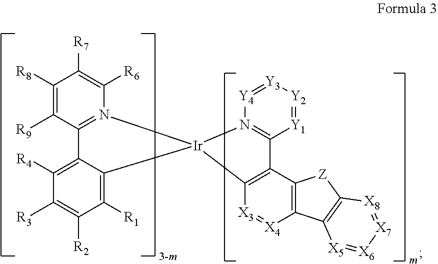

wherein
m is selected from 1, 2 or 3; preferably, m is selected from 1 or 2;
Z is selected from the group consisting of 0, S, Se, NR, CRR, SiRR, and GeRR; when two R are present, the two R are identical or different;
X₃ to X₈ are, at each occurrence identically or differently, selected from CRₓ;
Y₁ to Y₄ are, at each occurrence identically or differently, selected from CR_{y} or N;
R₁ to R₈, R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents in R₁ to R₈ can be optionally joined to form a ring; and
adjacent substituents R, Rₓ, and R_{y} can be optionally joined to form a ring.

Herein, the expression that “adjacent substituents in R₁ to R₈ can be optionally joined to form a ring” is intended to mean that any one or more of groups of adjacent substituents in R₁ to R₈ can be joined to form a ring. Obviously, it is also possible that these substituents are not joined to form a ring.

According to an embodiment of the present disclosure, Z is selected from O or S.

According to an embodiment of the present disclosure, Z is O.

According to an embodiment of the present disclosure, Rₓ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof.

According to an embodiment of the present disclosure, Rₓ is, at each occurrence identically or differently, selected from the group consisting of: hydrogen, deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 11 carbon atoms, substituted or unsubstituted alkylsilyl having 3 to 6 carbon atoms, a cyano group, and combinations thereof.

According to an embodiment of the present disclosure, at least one Rx is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, and combinations thereof

According to an embodiment of the present disclosure, at least one Rₓ is selected from the group consisting of: deuterium, fluorine, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 11 carbon atoms, substituted or unsubstituted alkylsilyl having 3 to 6 carbon atoms, a cyano group, and combinations thereof.

According to an embodiment of the present disclosure, at least one Rₓ is a cyano group or fluorine.

According to an embodiment of the present disclosure, X₇ is CRₓ, and Rₓ is a cyano group or fluorine; or X₈ is CRₓ, and Rₓ is a cyano group.

According to an embodiment of the present disclosure, at least two of X₅ to X₈ are CRₓ, one Rₓ is a cyano group or fluorine, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

According to an embodiment of the present disclosure, at least two of X₅ to X₈ are CRₓ, one Rₓ is a cyano group or fluorine, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted amino having 0 to 20 carbon atoms, a cyano group, a hydroxyl group, a sulfanyl group, and combinations thereof.

According to an embodiment of the present disclosure, at least two of X₅ to X₈ are CRₓ, one Rₓ is a cyano group or fluorine, and at least another one Rₓ is selected from the group consisting of: deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, and combinations thereof.

According to an embodiment of the present disclosure, X₇ and X₈ are both selected from CRₓ, one Rₓ is a cyano group or fluorine, and the other Rₓ is selected from the group consisting of: substituted or unsubstituted aryl having 6 to 30 carbon atoms, substituted or unsubstituted heteroaryl having 3 to 30 carbon atoms, and combinations thereof.

According to an embodiment of the present disclosure, at least one, at least two, at least three or all of R₂, R₃, R₆, and R₇ are selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, at least one, at least two, at least three or all of R₂, R₃, R₆, and R₇ are selected from the group consisting of: deuterium, substituted or unsubstituted alkyl having 1 to 20 carbon atoms, substituted or unsubstituted cycloalkyl having 3 to 20 ring carbon atoms, and combinations thereof.

According to an embodiment of the present disclosure, at least one, at least two, at least three or all of R₂, R₃, R₆, and R₇ are selected from the group consisting of: deuterium, methyl, ethyl, propyl, isopropyl, n-butyl, isobutyl, t-butyl, cyclopentyl, cyclohexyl, and combinations thereof; optionally, hydrogens in the above groups can be partially or fully substituted with deuterium.

According to an embodiment of the present disclosure, at least one or at least two of R₁ to R₈ are selected from substituted or unsubstituted alkyl having 1 to 20 carbon atoms, substituted or unsubstituted cycloalkyl having 3 to 20 ring carbon atoms or combinations thereof; the total number of carbon atoms in all of R₁ to R₄ and/or R₅ to R₈ is at least 4.

According to an embodiment of the present disclosure, at least one of R₅ to R₈ is selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof.

According to an embodiment of the present disclosure, at least one of R₅ to R₈ is selected from the group consisting of: deuterium, substituted or unsubstituted alkyl having 1 to 20 carbon atoms, substituted or unsubstituted cycloalkyl having 3 to 20 ring carbon atoms, and combinations thereof.

According to an embodiment of the present disclosure, at least one or at least two of R₁ to R₄ are selected from substituted or unsubstituted alkyl having 1 to 20 carbon atoms, substituted or unsubstituted cycloalkyl having 3 to 20 ring carbon atoms or combinations thereof, and the total number of carbon atoms in all of substituents R₁ to R₄ is at least 4.

According to an embodiment of the present disclosure, at least one or at least two of R₅ to R₈ are selected from substituted or unsubstituted alkyl having 1 to 20 carbon atoms, substituted or unsubstituted cycloalkyl having 3 to 20 ring carbon atoms or combinations thereof, and the total number of carbon atoms in all of substituents R₅ to R₈ is at least 4.

According to an embodiment of the present disclosure, at least one or at least two of the substituents R₁ to R₄ are selected from substituted or unsubstituted alkyl having 1 to 20 carbon atoms, substituted or unsubstituted cycloalkyl having 3 to 20 ring carbon atoms or combinations thereof, and the total number of carbon atoms in all of the substituents R₁ to R₄ is at least 4; at the same time, at least one or at least two of the substituents R₅ to R₈ are selected from substituted or unsubstituted alkyl having 1 to 20 carbon atoms, substituted or unsubstituted cycloalkyl having 3 to 20 ring carbon atoms or combinations thereof, and the total number of carbon atoms in all of the substituents R₅ to R₈ is at least 4.

According to an embodiment of the present disclosure, R₂ or R₃ is selected from substituted or unsubstituted alkyl having 1 to 20 carbon atoms, substituted or unsubstituted cycloalkyl having 3 to 20 ring carbon atoms or combinations thereof.

According to an embodiment of the present disclosure, R₂ or R₃ is selected from substituted or unsubstituted alkyl having 4 to 20 carbon atoms, substituted or unsubstituted cycloalkyl having 4 to 20 ring carbon atoms or combinations thereof.

According to an embodiment of the present disclosure, R₆ or R₇ is selected from substituted or unsubstituted alkyl having 1 to 20 carbon atoms, substituted or unsubstituted cycloalkyl having 3 to 20 ring carbon atoms or combinations thereof.

According to an embodiment of the present disclosure, R₆ or R₇ is selected from substituted or unsubstituted alkyl having 4 to 20 carbon atoms, substituted or unsubstituted cycloalkyl having 4 to 20 ring carbon atoms or combinations thereof.

According to another embodiment of the present disclosure, the first metal complex is, at each occurrence identically or differently, selected from the group consisting of, but not limited to, Metal Complex GD1 to Metal Complex GD18, wherein for specific structures of Metal Complex GD1 to Metal Complex GD18, reference is made to claim 19.

According to an embodiment of the present disclosure, hydrogens in Metal Complex GD1 to Metal Complex GD18 can be partially or fully substituted with deuterium.

According to an embodiment of the present disclosure, the second compound has a structure as show in Formula 4:

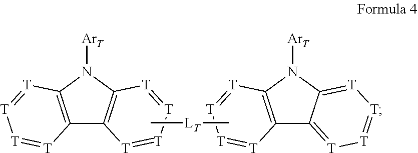

wherein
L_{T} is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
T is, at each occurrence identically or differently, selected from C, CRₜ or N;
Rₜ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Ar_{T} is, at each occurrence identically or differently, selected from substituted or unsubstituted aryl having 6 to 30 carbon atoms, substituted or unsubstituted heteroaryl having 3 to 30 carbon atoms or combinations thereof; and
adjacent substituents Rₜ can be optionally joined to form a ring.

Herein, the expression that “adjacent substituents Rₜ can be optionally joined to form a ring” is intended to mean that any one or more of groups of adjacent substituents, such as any two substituents Rₜ, can be joined to form a ring. Obviously, it is also possible that these substituents are not joined to form a ring.

According to an embodiment of the present disclosure, the second compound has a structure as show in Formula 4-1:

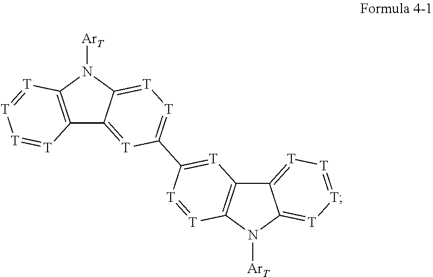

wherein
T is, at each occurrence identically or differently, selected from CRₜ or N;
Rₜ is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkenyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;

Ar_{T} is, at each occurrence identically or differently, selected from substituted or unsubstituted aryl having 6 to 30 carbon atoms, substituted or unsubstituted heteroaryl having 3 to 30 carbon atoms or combinations thereof; and
adjacent substituents Rₜ can be optionally joined to form a ring.

According to an embodiment of the present disclosure, the second compound is, at each occurrence identically or differently, selected from the group consisting of PH-1 to PH-28 and PH-29 to PH-38:

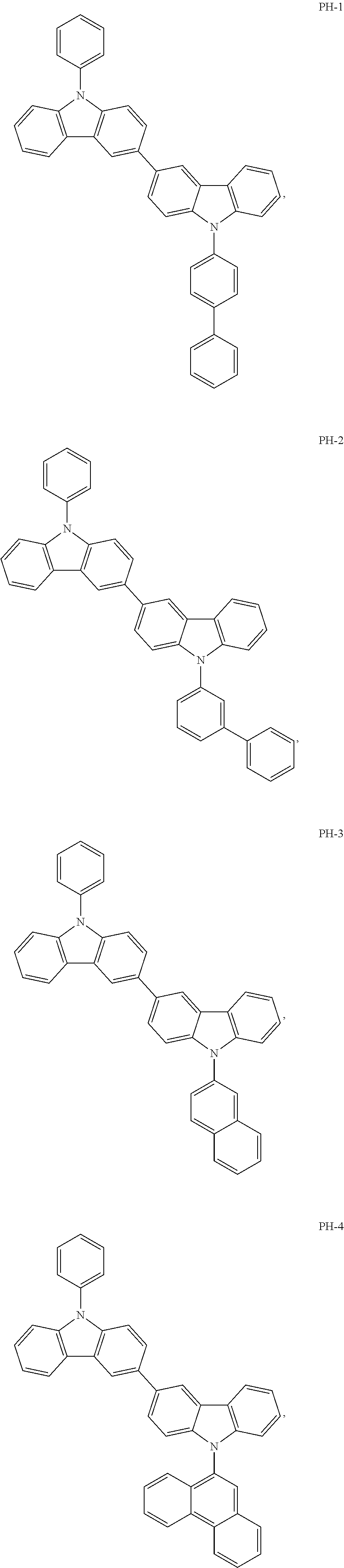 [SMILES: c1ccc(-c2ccc(-n3c4ccccc4c4cc(-c5ccc6c(c5)c5ccccc5n6-c5ccccc5)ccc43)cc2)cc1 ; c1ccc(-c2cccc(-n3c4ccccc4c4cc(-c5ccc6c(c5)c5ccccc5n6-c5ccccc5)ccc43)c2)cc1 ; c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cc5ccccc5c5ccccc45)ccc32)cc1]

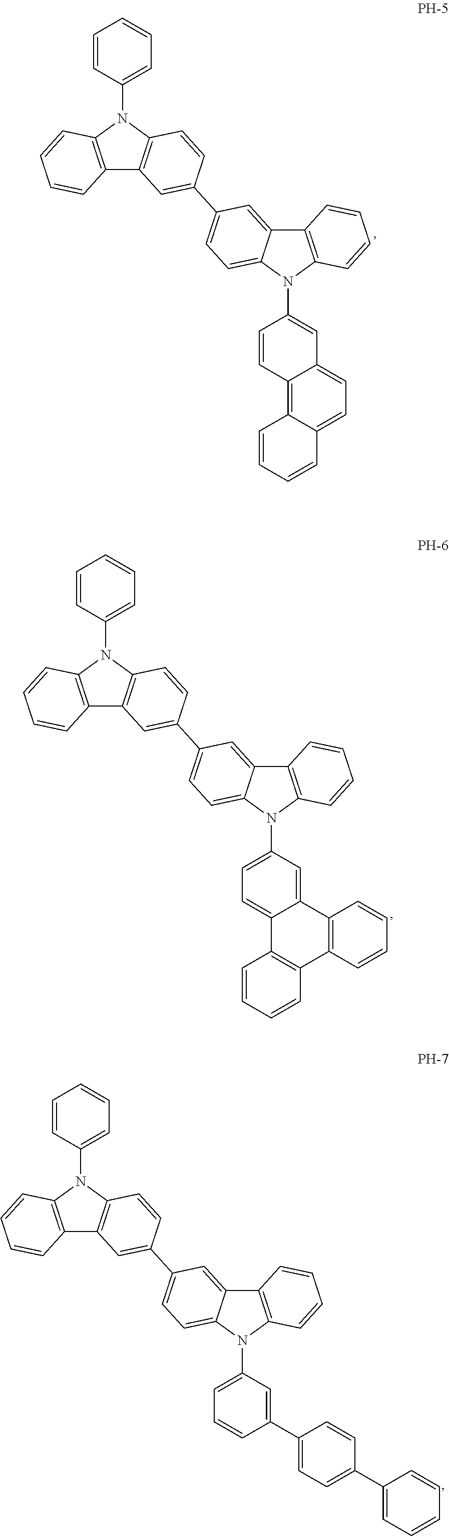 [SMILES: c1ccc(-n2c3ccccc3c3cc(-c4ccc5c(c4)c4ccccc4n5-c4ccc5c(ccc6ccccc65)c4)ccc32)cc1 ; c1ccc(-n2c3ccccc3c3cc(-c4ccc5c(c4)c4ccccc4n5-c4ccc5c6ccccc6c6ccccc6c5c4)ccc32)cc1 ; c1ccc(-c2ccc(-c3cccc(-n4c5ccccc5c5cc(-c6ccc7c(c6)c6ccccc6n7-c6ccccc6)ccc54)c3)cc2)cc1]

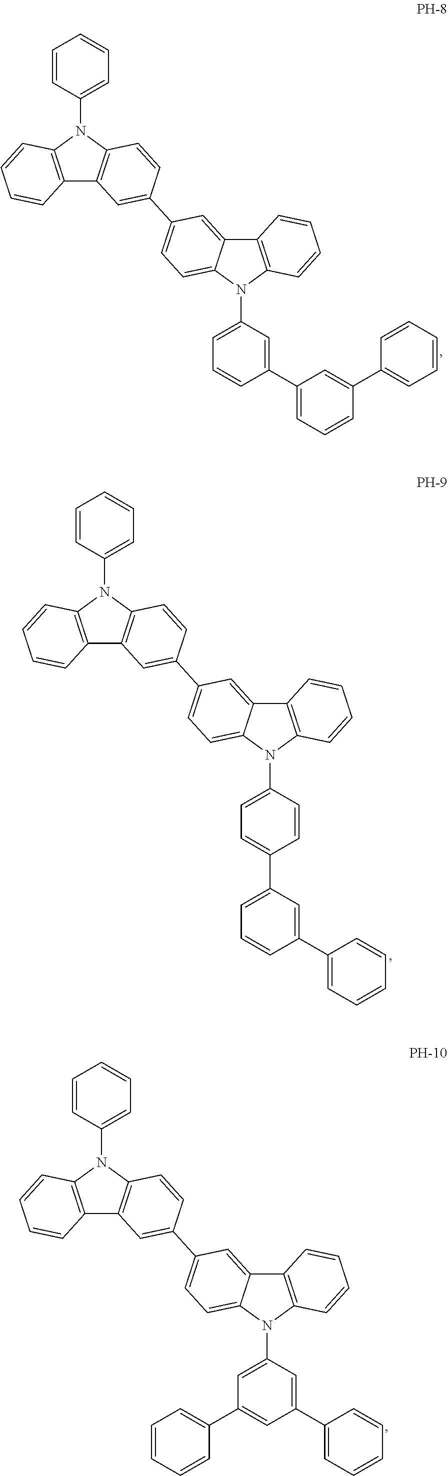 [SMILES: c1ccc(-c2cccc(-c3cccc(-n4c5ccccc5c5cc(-c6ccc7c(c6)c6ccccc6n7-c6ccccc6)ccc54)c3)c2)cc1 ; c1ccc(-c2cccc(-c3ccc(-n4c5ccccc5c5cc(-c6ccc7c(c6)c6ccccc6n7-c6ccccc6)ccc54)cc3)c2)cc1 ; c1ccc(-c2cc(-c3ccccc3)cc(-n3c4ccccc4c4cc(-c5ccc6c(c5)c5ccccc5n6-c5ccccc5)ccc43)c2)cc1]

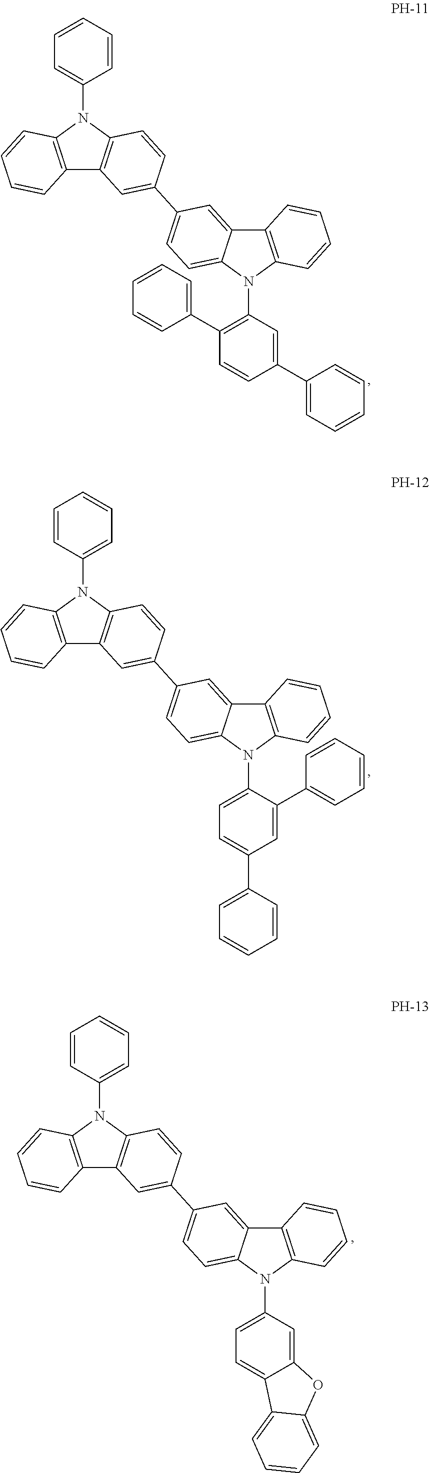 [SMILES: c1ccc(-c2ccc(-c3ccccc3)c(-n3c4ccccc4c4cc(-c5ccc6c(c5)c5ccccc5n6-c5ccccc5)ccc43)c2)cc1 ; c1ccc(-c2ccc(-n3c4ccccc4c4cc(-c5ccc6c(c5)c5ccccc5n6-c5ccccc5)ccc43)c(-c3ccccc3)c2)cc1 ; c1ccc(-n2c3ccccc3c3cc(-c4ccc5c(c4)c4ccccc4n5-c4ccc5c(c4)oc4ccccc45)ccc32)cc1]

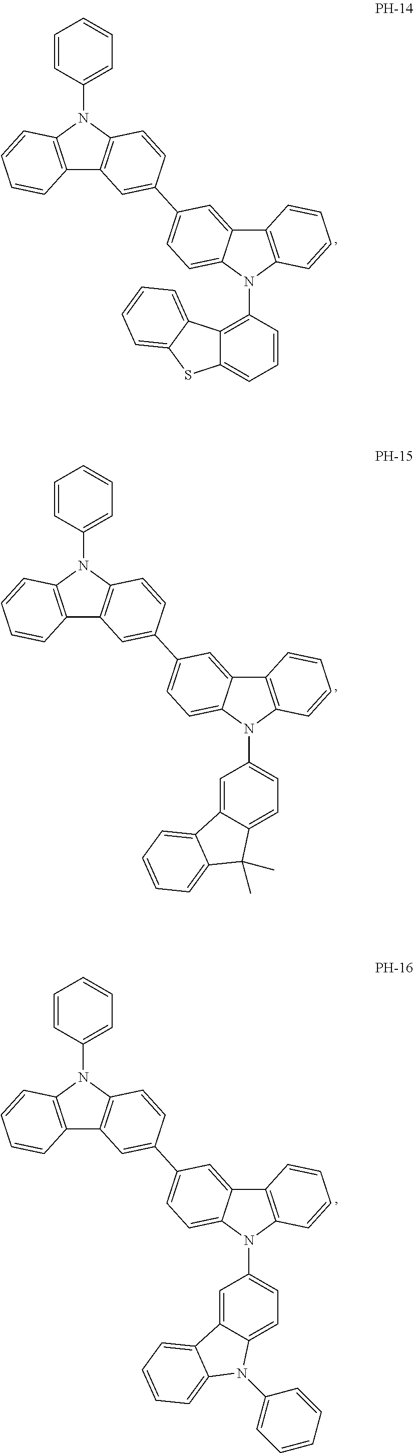 [SMILES: c1ccc(-n2c3ccccc3c3cc(-c4ccc5c(c4)c4ccccc4n5-c4cccc5sc6ccccc6c45)ccc32)cc1 ; CC1(C)c2ccccc2-c2cc(-n3c4ccccc4c4cc(-c5ccc6c(c5)c5ccccc5n6-c5ccccc5)ccc43)ccc21 ; c1ccc(-n2c3ccccc3c3cc(-c4ccc5c(c4)c4ccccc4n5-c4ccc5c(c4)c4ccccc4n5-c4ccccc4)ccc32)cc1]

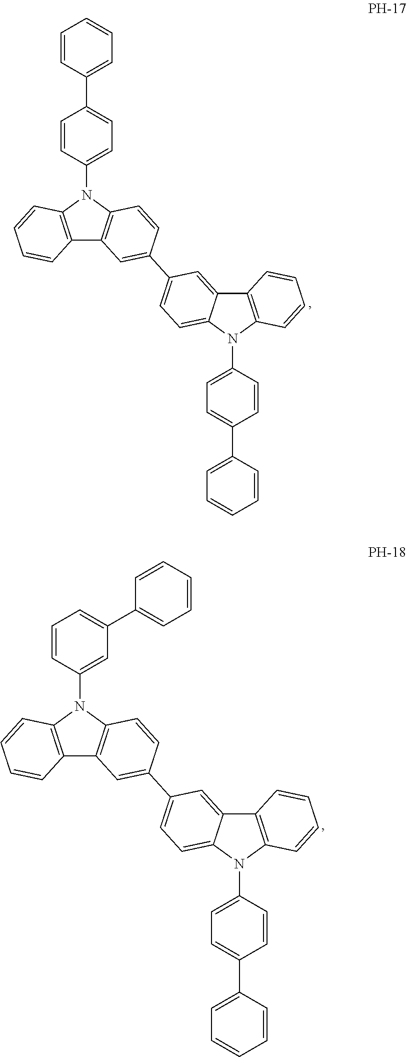 [SMILES: c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

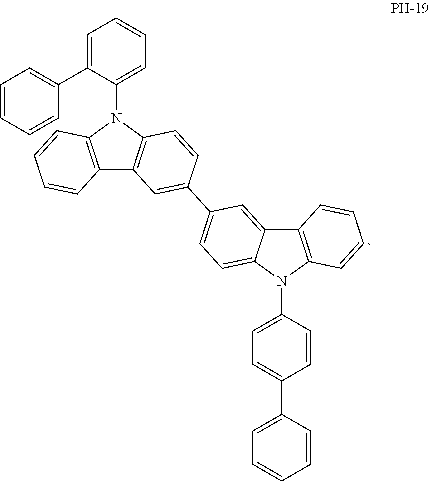 [SMILES: c1ccc(-c2ccc(-n3c4ccccc4c4cc(-c5ccc6c(c5)c5ccccc5n6-c5ccccc5-c5ccccc5)ccc43)cc2)cc1]

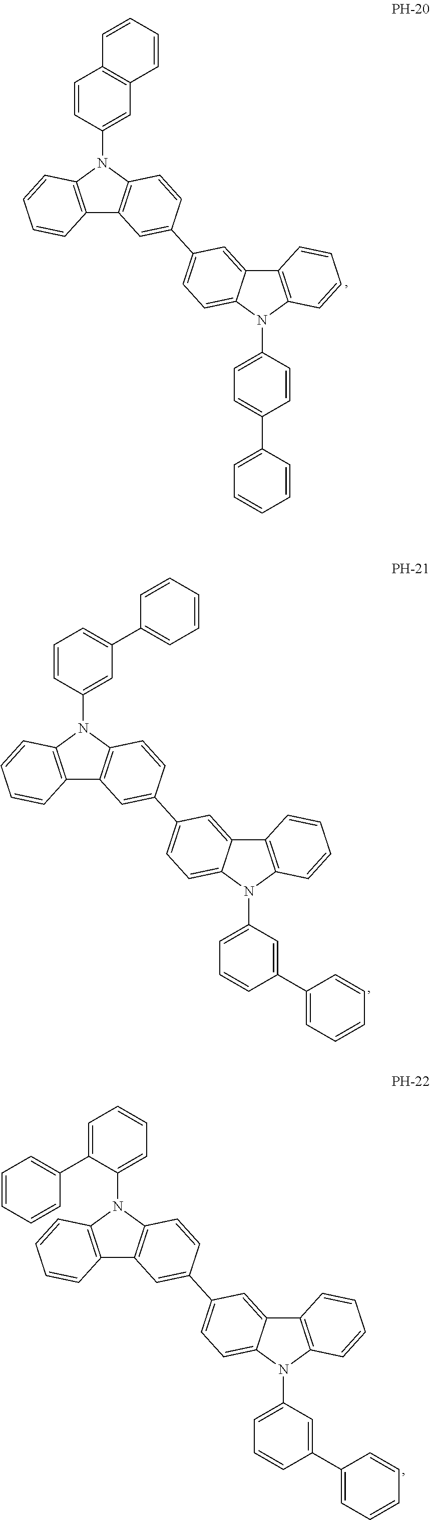 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1]

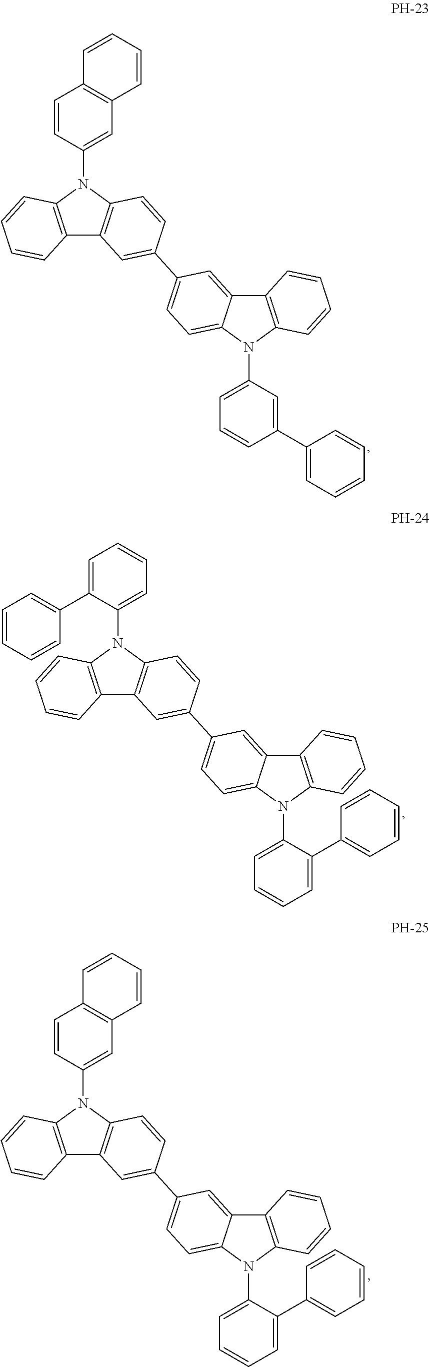 [SMILES: c1ccc(-c2cccc(-n3c4ccccc4c4cc(-c5ccc6c(c5)c5ccccc5n6-c5ccc6ccccc6c5)ccc43)c2)cc1 ; c1ccc(-c2ccccc2-n2c3ccccc3c3cc(-c4ccc5c(c4)c4ccccc4n5-c4ccccc4-c4ccccc4)ccc32)cc1 ; c1ccc(-c2ccccc2-n2c3ccccc3c3cc(-c4ccc5c(c4)c4ccccc4n5-c4ccc5ccccc5c4)ccc32)cc1]

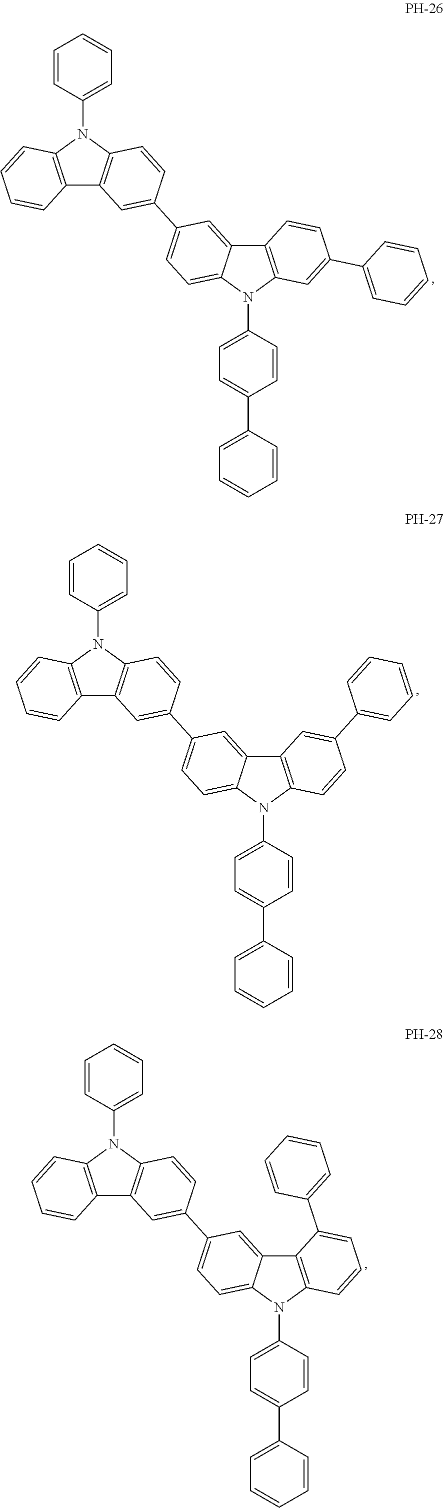 [SMILES: c1ccc(-c2ccc(-n3c4ccc(-c5ccc6c(c5)c5ccccc5n6-c5ccccc5)cc4c4ccc(-c5ccccc5)cc43)cc2)cc1 ; c1ccc(-c2ccc(-n3c4ccc(-c5ccccc5)cc4c4cc(-c5ccc6c(c5)c5ccccc5n6-c5ccccc5)ccc43)cc2)cc1 ; c1ccc(-c2ccc(-n3c4ccc(-c5ccc6c(c5)c5ccccc5n6-c5ccccc5)cc4c4c(-c5ccccc5)cccc43)cc2)cc1]

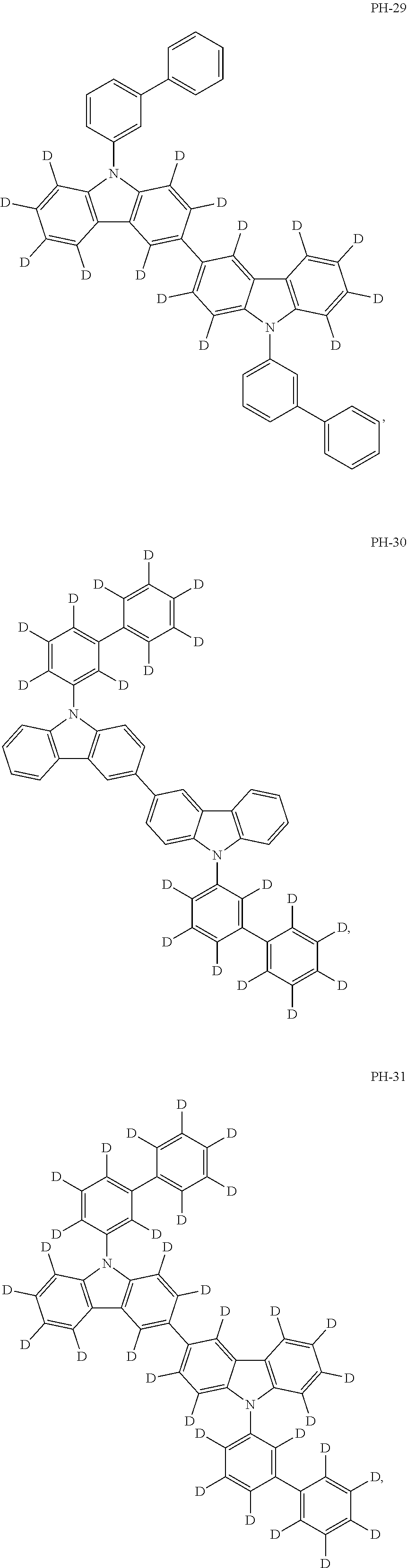

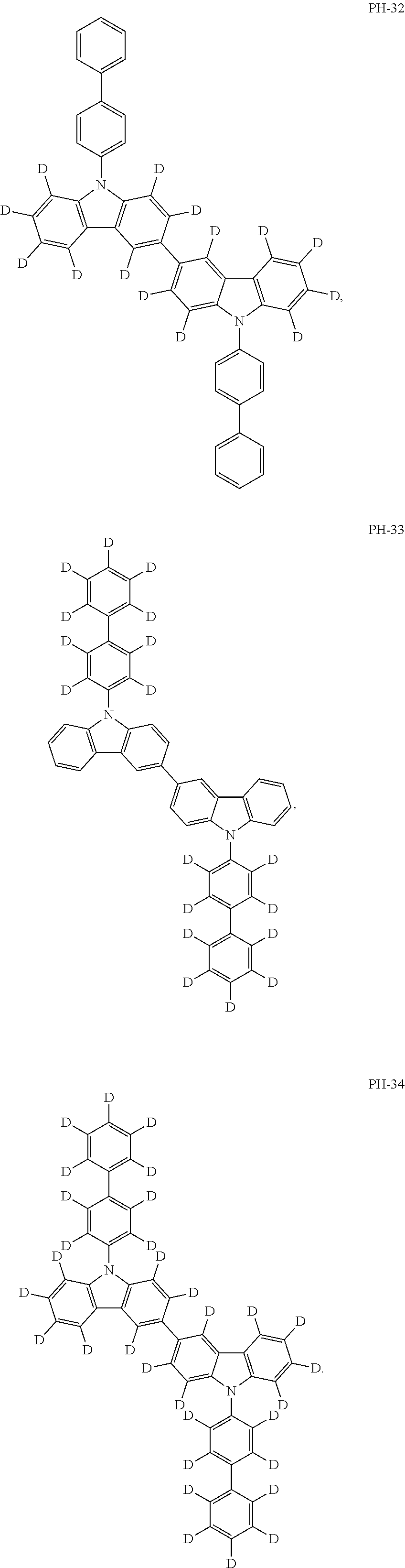

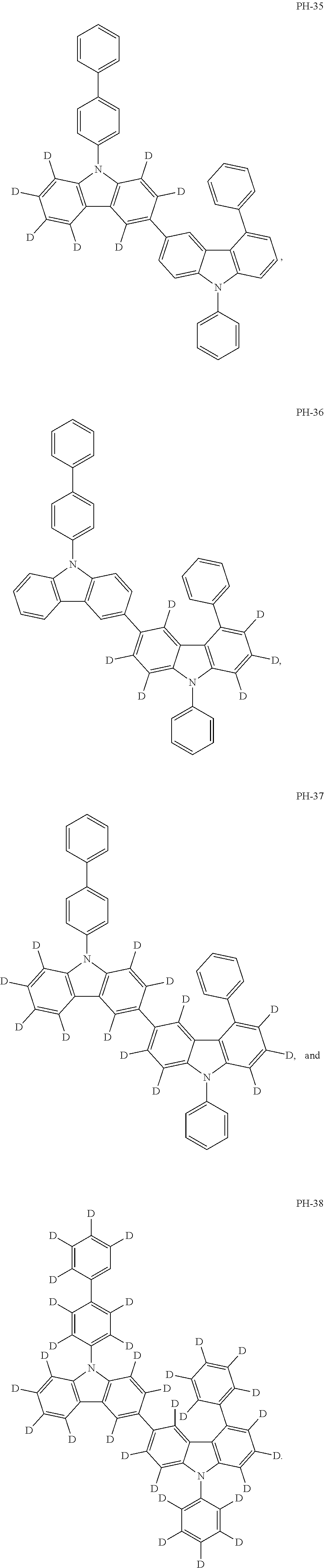

According to an embodiment of the present disclosure, hydrogens in Compound PH-1 to Compound PH-28 can be partially or fully substituted with deuterium.

According to an embodiment of the present disclosure, hydrogens in Compound PH-1 to Compound PH-38 can be partially or fully substituted with deuterium.

According to an embodiment of the present disclosure, the organic electroluminescent device further includes a hole injection layer. The hole injection layer may be a functional layer containing a single material or a functional layer containing a variety of materials, wherein the most commonly used ones among the variety of materials contained are hole transport materials doped with a certain proportion of a p-type conductive doped material. Common p-type doped materials are as follows:

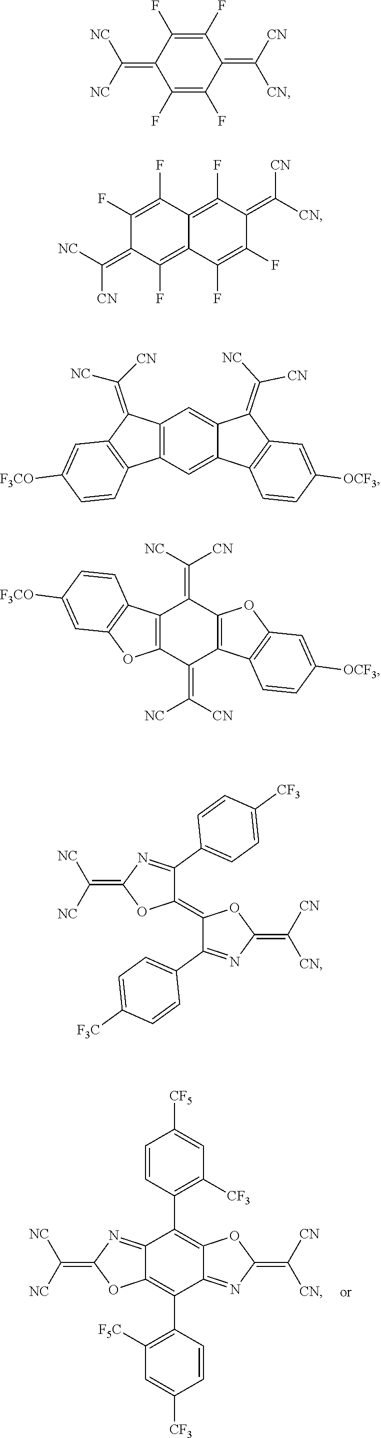

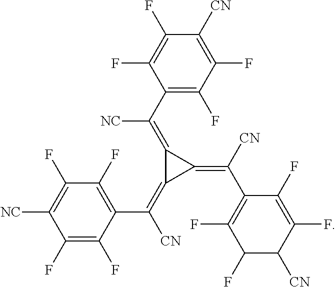 [SMILES: N#C/C(=C1\C(=C(\C#N)C2=C(F)C(F)C(C#N)C(F)=C2F)\C1=C(\C#N)c1c(F)c(F)c(C#N)c(F)c1F)c1c(F)c(F)c(C#N)c(F)c1F]

According to an embodiment of the present disclosure, an organic electroluminescent device is disclosed. The organic electroluminescent device includes a cathode, an anode, and an organic layer disposed between the cathode and the anode;
the organic layer includes a first emissive layer, and the first emissive layer includes a first compound and a first metal complex;
the capacitance characteristic of the organic electroluminescent device satisfies the following conditions:
at 500 Hz, the maximum value of the capacitance per unit of emissive area of the organic electroluminescent device is Cₘₐₓ₋ₛ nF/cm²; and
at 500 Hz, the maximum value of the capacitance per unit of emissive area of an organic electroluminescent device using the compound GH0 to replace the first compound in the first emissive layer is Cₘₐₓ₀₋ₛ nF/cm²;

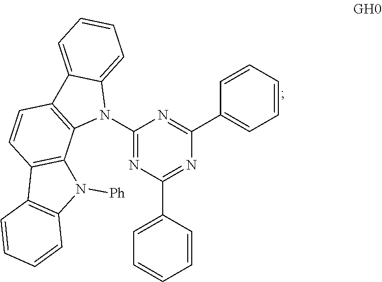 [SMILES: c1ccc(-c2nc(-c3ccccc3)nc(-n3c4ccccc4c4ccc5c6ccccc6n(-c6ccccc6)c5c43)n2)cc1]

wherein Cₘₐₓ₋ₛ−Cₘₐₓ₀₋ₛ≤−8.75 nF/cm²;
the first metal complex has a general formula of M(Lₐ)ₘ(L_{b})ₙ(L_{c})_{q};
M is selected from a metal with a relative atomic mass greater than 40;
Lₐ, L_{b}, and L_{c} are a first ligand, a second ligand, and a third ligand coordinated to the metal M, respectively, and Lₐ, L_{b}, and L_{c} are identical or different; wherein Lₐ, L_{b}, and L_{c} can be optionally joined to form a tetradentate ligand or a multidentate ligand;
m is selected from 1, 2 or 3, n is selected from 0, 1 or 2, q is selected from 0, 1 or 2, and m+n+q equals an oxidation state of the metal M; when m is greater than or equal to 2, a plurality of Lₐ are identical or different; when n is equal to 2, two L_{b} are identical or different; when q is equal to 2, two L_{c} are identical or different;
the ligand Lₐ has a structure represented by Formula 1:

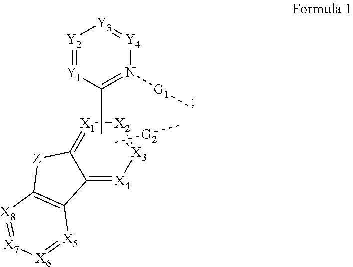

wherein
Z is selected from the group consisting of O, S, Se, NR, CRR, SiRR, and GeRR; when two R are present, the two R are identical or different;
G₁ and G₂ are, at each occurrence identically or differently, selected from a single bond, O or S;
two of X₁ to X₄ are selected from C, one of the two C is joined to the N-containing ring shown in Formula 1, the other one of the two C is joined to the metal via G₂, and the remaining two of X₁ to X₄ are each independently selected from CRₓ;
X₅ to X₈ are, at each occurrence identically or differently, selected from CRₓ;
Y₁ to Y₄ are, at each occurrence identically or differently, selected from CR_{y} or N;
R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R, Rₓ, and R_{y} can be optionally joined to form a ring; and
L_{b} and L_{c} are, at each occurrence identically or differently, selected from a monoanionic multidentate ligand.

According to an embodiment of the present disclosure, at 500 Hz, for the maximum value of the capacitance per unit of emissive area of the organic electroluminescent device, 12.5 nF/cm²≤Cₘₐₓ₋ₛ≤137.5 nF/cm².

According to an embodiment of the present disclosure, at 500 Hz, for the maximum value of the capacitance per unit of emissive area of the organic electroluminescent device, 25 nF/cm²≤Cₘₐₓ₋ₛ≤100 nF/cm².

According to an embodiment of the present disclosure, at 500 Hz, for the maximum value of the capacitance per unit of emissive area of the organic electroluminescent device, 25 nF/cm²≤Cₘₐₓ₋ₛ≤75 nF/cm².

According to an embodiment of the present disclosure, Cₘₐₓ₋ₛ−Cₘₐₓ₀₋ₛ≤−11.25 nF/cm².

According to an embodiment of the present disclosure, Cₘₐₓ₋ₛ−Cₘₐₓ₀₋ₛ≤−13.75 nF/cm².

According to an embodiment of the present disclosure, a display assembly is further disclosed. The display assembly includes the organic electroluminescent device described in any one of the preceding embodiments.

### Combination with Other Materials

The materials described in the present disclosure for a particular layer in an organic light-emitting device can be used in combination with various other materials present in the device. The combinations of these materials are described in more detail in U.S. Pat. App. No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light-emitting device may be used in combination with a variety of other materials present in the device. For example, dopants disclosed herein may be used in combination with a wide variety of hosts, transport layers, blocking layers, injection layers, electrodes and other layers that may be present. The combination of these materials is described in detail in paragraphs 0080-0101 of U.S. Pat. App. No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

In the embodiments of material synthesis, all reactions were performed under nitrogen protection unless otherwise stated. All reaction solvents were anhydrous and used as received from commercial sources. Synthetic products were structurally confirmed and tested for properties using one or more conventional equipment in the art (including, but not limited to, nuclear magnetic resonance instrument produced by BRUKER, liquid chromatograph produced by SHIMADZU, liquid chromatograph-mass spectrometry produced by SHIMADZU, gas chromatograph-mass spectrometry produced by SHIMADZU, differential Scanning calorimeters produced by SHIMADZU, fluorescence spectrophotometer produced by SHANGHAI LENGGUANG TECH., electrochemical workstation produced by WUHAN CORRTEST, and sublimation apparatus produced by ANHUI BEQ, etc.) by methods well known to the persons skilled in the art. In the embodiments of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well known to the persons skilled in the art. As the persons skilled in the art are aware of the above-mentioned equipment use, test methods and other related contents, the inherent data of the sample can be obtained with certainty and without influence, so the above related contents are not further described in this patent.

The electrochemical properties of the compounds, including the highest occupied molecular orbital energy level and the lowest unoccupied molecular orbital energy level, were measured by cyclic voltammetry (CV). The test was conducted using an electrochemical workstation, Model No. CorrTest CS120, produced by WUHAN CORRTEST INSTRUMENTS CORP., LTD., and using a three-electrode working system where a platinum disk electrode served as a working electrode, an Ag/AgNO₃ electrode served as a reference electrode, and a platinum wire electrode served as an auxiliary electrode. Anhydrous DMF was used as a solvent, 0.1 mol/L tetrabutylammonium hexafluorophosphate was used as a supporting electrolyte, a compound to be tested was prepared into a solution of 10⁻³ mol/L, and nitrogen was introduced into the solution for 10 min for oxygen removal before the test. The parameters of the instrument were set as follows: the scan rate was 100 mV/s, the potential interval was 0.5 mV, the oxidation potential test window was 0 V to 1 V, and the reduction potential test window was −1 V to −2.9 V. The energy level data of the first compound and the compound GH0 used in the present application measured by the above method are shown in Table 1 below.

TABLE 1
Energy level data of the first compound and the compound GH0

| Compound | LUMO/eV |
|---|---|
| A-9 | −2.884 |
| A-22 | −2.905 |
| A-19 | −2.856 |
| A-15 | −2.899 |
| GH0 | −2.712 |

The structures of the preceding compounds are as follows:

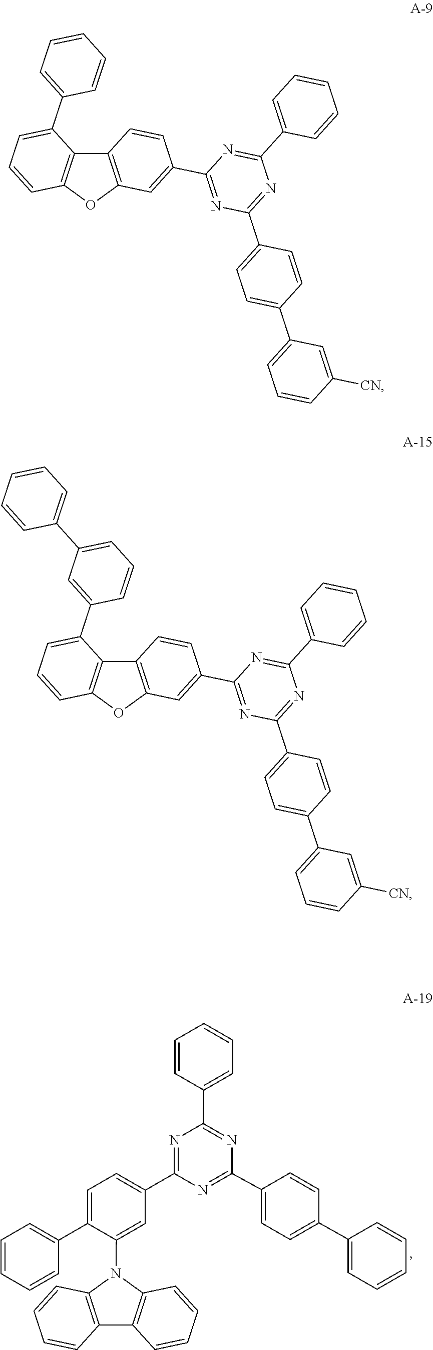 [SMILES: N#Cc1cccc(-c2ccc(-c3nc(-c4ccccc4)nc(-c4ccc5c(c4)oc4cccc(-c6ccccc6)c45)n3)cc2)c1 ; N#Cc1cccc(-c2ccc(-c3nc(-c4ccccc4)nc(-c4ccc5c(c4)oc4cccc(-c6cccc(-c7ccccc7)c6)c45)n3)cc2)c1 ; c1ccc(-c2ccc(-c3nc(-c4ccccc4)nc(-c4ccc(-c5ccccc5)c(-n5c6ccccc6c6ccccc65)c4)n3)cc2)cc1]

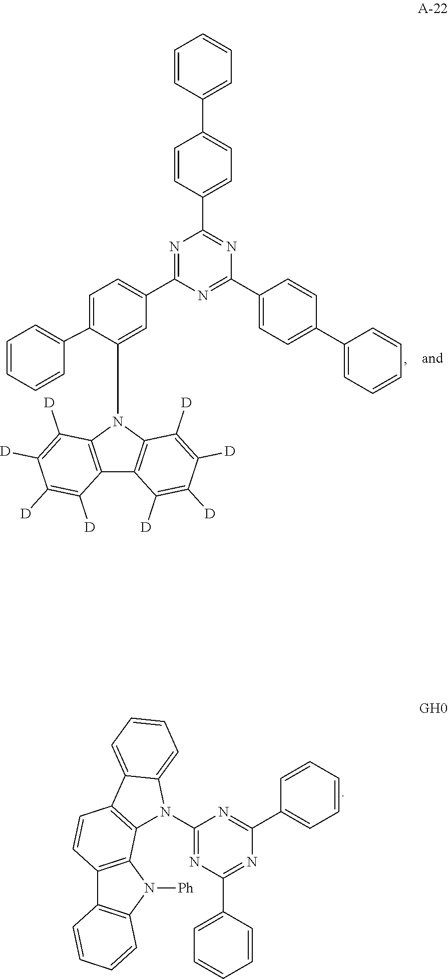 [SMILES: [2H]c1c([2H])c([2H])c2c(c1[2H])c1c([2H])c([2H])c([2H])c([2H])c1n2-c1cc(-c2nc(-c3ccc(-c4ccccc4)cc3)nc(-c3ccc(-c4ccccc4)cc3)n2)ccc1-c1ccccc1 ; c1ccc(-c2nc(-c3ccccc3)nc(-n3c4ccccc4c4ccc5c6ccccc6n(-c6ccccc6)c5c43)n2)cc1]

### Device Example

### Device Example 1

First, a glass substrate having an indium tin oxide (ITO) anode (whose sheet resistance was 14 to 20 Ω/sq and emission area was 0.04 cm²) with a thickness of 80 nm was cleaned and then treated with oxygen plasma and UV ozone. After the treatment, the substrate was dried in a glovebox to remove moisture. Then, the substrate was mounted on a substrate holder and placed in a vacuum chamber. The organic layers specified below were sequentially deposited through vacuum thermal evaporation on the ITO anode at a rate of 0.2 to 2 Angstroms (A) per second at a vacuum degree of about 10⁻⁸ torr. Compound HI was deposited as a hole injection layer (HIL). Compound HT was deposited as a hole transport layer (HTL). Compound PH-17 was deposited as an electron blocking layer (EBL). Metal Complex GD1, Compound PH-17 and Compound A-9 were co-deposited as an emissive layer (EML). On the EML, Compound GH0 was deposited as a hole blocking layer (HBL). On the HBL, Compound ET and 8-hydroxyquinolinolato-lithium (Liq) were co-deposited as an electron transport layer (ETL). Finally, 8-hydroxyquinolinolato-lithium (Liq) with a thickness of 1 nm was deposited as an electron injection layer, and Al with a thickness of 120 nm was deposited as a cathode. The device was transferred back to the glovebox and encapsulated with a glass lid and a moisture absorbent to complete the device.

### Device Example 2

The implementation of Device Example 2 was the same as that of Device Example 1, except that Compound A-9 of the present disclosure was replaced with Compound A-22 in the emissive layer (EML).

### Device Example 3

The implementation of Device Example 3 was the same as that of Device Example 1, except that Compound A-9 of the present disclosure was replaced with Compound A-19 in the emissive layer (EML).

### Device Example 4

The implementation of Device Example 4 was the same as that of Device Example 1, except that Compound A-9 of the present disclosure was replaced with Compound A-15 in the emissive layer (EML).

### Device Comparative Example 1

The implementation of Device Comparative Example 1 was the same as that of Device Example 1, except that Compound A-9 of the present disclosure was replaced with Compound GH0 in the emissive layer (EML).

Detailed structures and thicknesses of layers of the devices are shown in Table 2. The layers using more than one material were obtained by doping different compounds at their mass ratios as recorded.

TABLE 2
Device structures in Examples 1 to 4 and Comparative Example 1

| Device ID | HIL | HTL | EBL | EML | HBL | ETL |
|---|---|---|---|---|---|---|
| Example 1 | Compound | Compound | Compound | Compound | Compound | Compound |
| | HI | HT | PH-17 | PH-17:Compound | GH0 | ET:Liq |
| | (100 Å) | (350 Å) | (50 Å) | A-9:Metal | (50 Å) | (40:60) |
| | | | | Complex GD1 | | (350 Å) |
| | | | | (47:47:6) (400 Å) | | |
| Example 2 | Compound | Compound | Compound | Compound | Compound | Compound |
| | HI | HT | PH-17 | PH-17:Compound | GH0 | ET:Liq |
| | (100 Å) | (350 Å) | (50 Å) | A-22:Metal | (50 Å) | (40:60) |
| | | | | Complex GD1 | | (350 Å) |
| | | | | (47:47:6) (400 Å) | | |
| Example 3 | Compound | Compound | Compound | Compound | Compound | Compound |
| | HI | HT | PH-17 | PH-17:Compound | GH0 | ET:Liq |
| | (100 Å) | (350 Å) | (50 Å) | A-19:Metal | (50 Å) | (40:60) |
| | | | | Complex GD1 | | (350 Å) |
| | | | | (47:47:6) (400 Å) | | |
| Example 4 | Compound | Compound | Compound | Compound | Compound | Compound |
| | HI | HT | PH-17 | PH-17:Compound | GH0 | ET:Liq |
| | (100 Å) | (350 Å) | (50 Å) | A-15:Metal | (50 Å) | (40:60) |
| | | | | Complex GD1 | | (350 Å) |
| | | | | (47:47:6) (400 Å) | | |
| Comparative | Compound | Compound | Compound | Compound | Compound | Compound |
| Example 1 | HI | HT | PH-17 | PH-17:Compound | GH0 | ET:Liq |
| | (100 Å) | (350 Å) | (50 Å) | GH0:Metal | (50 Å) | (40:60) |
| | | | | Complex GD1 | | (350 Å) |
| | | | | (47:47:6) (400 Å) | | |

The structures of the materials used in the devices are as follows:

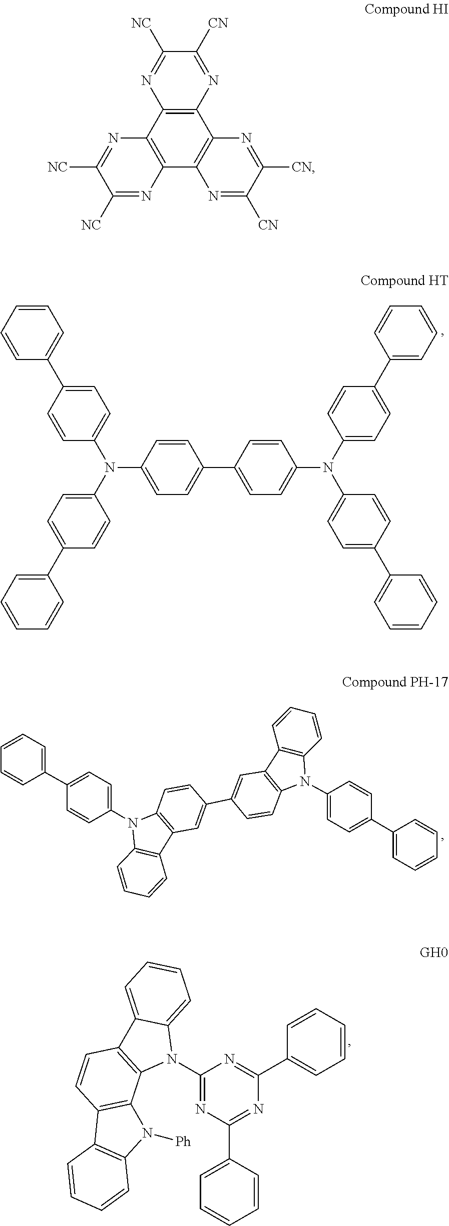 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccccc3)nc(-n3c4ccccc4c4ccc5c6ccccc6n(-c6ccccc6)c5c43)n2)cc1]

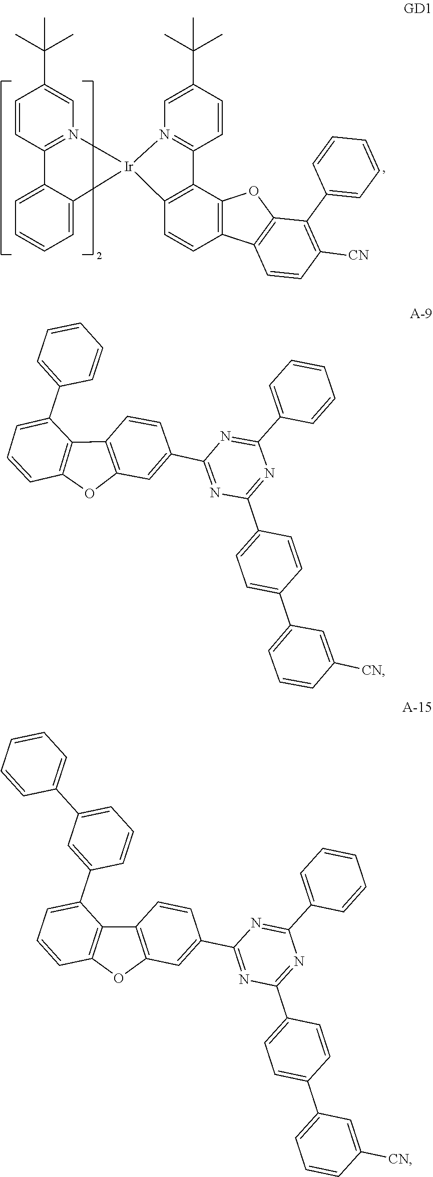

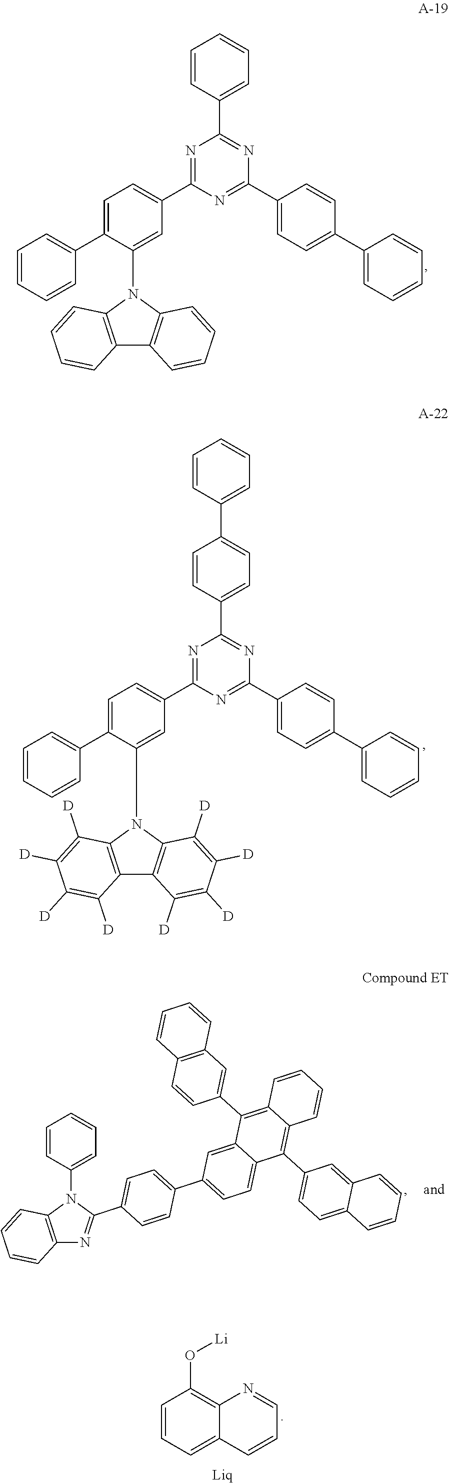

The capacitance of the device was tested using an impedance analyzer (Model No. Keysight E4990A). A direct current bias voltage of −4 V to 5 V was applied to the electrodes at both ends of the device, a sinusoidal alternating current voltage signal of 100 mV was additionally applied, and the capacitance was separately tested at an alternating current voltage with a frequency of 500 Hz. The C-V curve of the device was measured, the initial voltages (Vₜ and Vₜ₀), the voltages (V_{Cmax} and V_{Cmax0}) corresponding to the maximum capacitance, the maximum capacitance (Cₘₐₓ and Cₘₐₓ₀) of the device were obtained, and these data are recorded and shown in Table 3.

TABLE 3
Data of Examples 1 to 4 and Comparative Example 1

| | | Voltage | | |
|---|---|---|---|---|
| | Initial | corresponding | Maximum | |
| | voltage | to the maximum | capacitance | Cₘₐₓ − Cₘₐₓ₀ |
| Device ID | [V] | capacitance [V] | [nF] | [nF] |
| Example 1 | −2.25 | 2.12 | 2.13 | −2.0 |
| Example 2 | −1.26 | 2.21 | 3.29 | −0.84 |
| Example 3 | −1.08 | 2.30 | 3.74 | −0.39 |
| Example 4 | −1.44 | 2.12 | 2.64 | −1.49 |
| Comparative | −2.92 | 2.30 | 4.13 | 0.00 |
| Example1 | | | | |

As can be seen from the data shown in Table 3, Device Examples 1 to 4 and Comparative Example 1 all use the same metal complex GD1 as the emissive material in the emissive layer, and the metal complex has a ligand Lₐ having a structure represented by Formula 1 of the present application; Device Examples 1 to 4 use Compounds A-9, A-22, A-19, and A-15 as the first compound in the emissive layer, respectively, and compared with the maximum capacitance in Device Comparative Example 1 using GH0 as the first compound in the emissive layer, the maximum capacitance in Device Examples 1 to 4 is significantly reduced, by 2.0 nF, 0.84 nF, 0.39 nF, and 1.49 nF, respectively. The above shows that in the present disclosure, by selecting the combination of the materials (the combination of the first compound and the first metal complex) in the emissive layer of the organic electroluminescent device, the electron and hole balance of the device can be improved, and the capacitance of the device can be reduced, thereby improving the response time and the refresh frequency of the device at low grayscales.

### Device Example 5

The implementation of Device Example 5 was the same as that of Device Example 1, except that Metal Complex GD1 was replaced with Metal Complex GD2 in the emissive layer (EML).

### Device Example 6

The implementation of Device Example 6 was the same as that of Device Example 5, except that Compound A-9 of the present disclosure was replaced with Compound A-22 in the emissive layer (EML).

### Device Example 7

The implementation of Device Example 7 was the same as that of Device Example 5, except that Compound A-9 of the present disclosure was replaced with Compound A-19 in the emissive layer (EML).

### Device Comparative Example 2

The implementation of Device Comparative Example 2 was the same as that of Device Example 5, except that Compound A-9 of the present disclosure was replaced with Compound GH0 in the emissive layer (EML).

Detailed structures and thicknesses of layers of the devices are shown in Table 4. The layers using more than one material were obtained by doping different compounds at their mass ratios as recorded.

TABLE 4
Device structures in Examples 5 to 7 and Comparative Example 2

| Device ID | HIL | HTL | EBL | EML | HBL | ETL |
|---|---|---|---|---|---|---|
| Example 5 | Compound | Compound | Compound | Compound | Compound | Compound |
| | HI | HT | PH-17 | PH-17:Compound | GH0 | ET:Liq |
| | (100 Å) | (350 Å) | (50 Å) | A-9:Metal | (50 Å) | (40:60) |
| | | | | Complex GD2 | | (350 Å) |
| | | | | (47:47:6) (400 Å) | | |
| Example 6 | Compound | Compound | Compound | Compound | Compound | Compound |
| | HI | HT | PH-17 | PH-17:Compound | GH0 | ET:Liq |
| | (100 Å) | (350 Å) | (50 Å) | A-22:Metal | (50 Å) | (40:60) |
| | | | | Complex GD2 | | (350 Å) |
| | | | | (47:47:6) (400 Å) | | |
| Example 7 | Compound | Compound | Compound | Compound | Compound | Compound |
| | HI | HT | PH-17 | PH-17:Compound | GH0 | ET:Liq |
| | (100 Å) | (350 Å) | (50 Å) | A-19:Metal | (50 Å) | (40:60) |
| | | | | Complex GD2 | | (350 Å) |
| | | | | (47:47:6) (400 Å) | | |
| Comparative | Compound | Compound | Compound | Compound | Compound | Compound |
| Example 2 | HI | HT | PH-17 | PH-17:Compound | GH0 | ET:Liq |
| | (100 Å) | (350 Å) | (50 Å) | GH0:Metal | (50 Å) | (40:60) |
| | | | | Complex GD2 | | (350 Å) |
| | | | | (47:47:6) (400 Å) | | |

The new material used in the devices has the following structure:

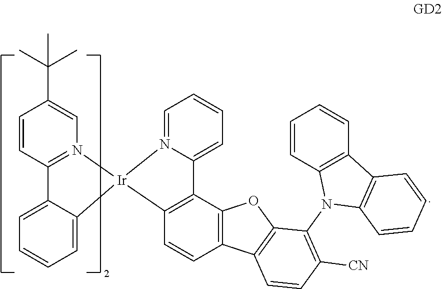

The capacitance of the device was tested using an impedance analyzer (Model No. Keysight E4990A). A direct current bias voltage of −4 V to 5 V was applied to the electrodes at both ends of the device, a sinusoidal alternating current voltage signal of 100 mV was additionally applied, and the capacitance was separately tested at an alternating current voltage with a frequency of 500 Hz. The C-V curve of the device was measured, the initial voltages (Vₜ and Vₜ₀), the voltages (V_{Cmax} and V_{Cmax0}) corresponding to the maximum capacitance, the maximum capacitance (Cₘₐₓ and Cₘₐₓ₀) of the device were obtained, and these data are recorded and shown in Table 5.

TABLE 5
Data in Examples 5 to 7 and Comparative Example 2

| | | Voltage | | |
|---|---|---|---|---|
| | initial | corresponding | Maximum | |
| | voltage | to the maximum | capacitance | Cₘₐₓ − Cₘₐₓ₀ |
| Device ID | [V] | capacitance [V] | [nF] | [nF] |
| Example 5 | −1.12 | 2.12 | 2.63 | −1.42 |
| Example 6 | −0.76 | 2.26 | 3.22 | −0.83 |
| Example 7 | −0.45 | 2.26 | 3.20 | −0.85 |
| Comparative | −2.34 | 2.35 | 4.05 | 0.00 |
| Example 2 | | | | |

As can be seen from the data shown in Table 5, Device Examples 5 to 7 and Comparative Example 2 all use the same metal complex GD2 as the emissive material in the emissive layer, and the metal complex has a ligand Lₐ having a structure represented by Formula 1 of the present application; Device Examples 5 to 7 use Compounds A-9, A-22, and A-19 as the first compound in the emissive layer, respectively, and compared with the maximum capacitance in Device Comparative Example 2 using GH0 as the first compound in the emissive layer, the maximum capacitance in Device Examples 5 to 7 is significantly reduced, by 1.42 nF, 0.83 nF, and 0.85 nF, respectively. The above shows that in the present disclosure, by selecting the combination of the materials (the combination of the first compound and the first metal complex) in the emissive layer of the organic electroluminescent device, the electron and hole balance of the device can be improved, and the capacitance of the device can be reduced, thereby improving the response time and the refresh frequency of the device at low grayscales.

### Device Example 8

The implementation of Device Example 8 was the same as that of Device Example 1, except that Metal Complex GD1 was replaced with Metal Complex GD3 in the emissive layer (EML).

### Device Example 9

The implementation of Device Example 9 was the same as that of Device Example 8, except that Compound A-9 of the present disclosure was replaced with Compound A-22 in the emissive layer (EML).

### Device Example 10

The implementation of Device Example 10 was the same as that of Device Example 8, except that Compound A-9 of the present disclosure was replaced with Compound A-19 in the emissive layer (EML).

### Device Comparative Example 3

The implementation of Device Comparative Example 3 was the same as that of Device Example 8, except that Compound A-9 of the present disclosure was replaced with Compound GH0 in the emissive layer (EML).

Detailed structures and thicknesses of layers of the devices are shown in Table 6. The layers using more than one material were obtained by doping different compounds at their mass ratios as recorded.

TABLE 6
Device structures in Examples 8 to 10 and Comparative Example 3

| Device ID | HIL | HTL | EBL | EML | HBL | ETL |
|---|---|---|---|---|---|---|
| Example 8 | Compound | Compound | Compound | Compound | Compound | Compound |
| | HI | HT | PH-17 | PH-17:Compound | GH0 | ET:Liq |
| | (100 Å) | (350 Å) | (50 Å) | A-9:Metal | (50 Å) | (40:60) |
| | | | | Complex GD3 | | (350 Å) |
| | | | | (47:47:6) (400 Å) | | |
| Example 9 | Compound | Compound | Compound | Compound | Compound | Compound |
| | HI | HT | PH-17 | PH-17:Compound | GH0 | ET:Liq |
| | (100 Å) | (350 Å) | (50 Å) | A-22:Metal | (50 Å) | (40:60) |
| | | | | Complex GD3 | | (350 Å) |
| | | | | (47:47:6) (400 Å) | | |
| Example 10 | Compound | Compound | Compound | Compound | Compound | Compound |
| | HI | HT | PH-17 | PH-17:Compound | GH0 | ET:Liq |
| | (100 Å) | (350 Å) | (50 Å) | A-19:Metal | (50 Å) | (40:60) |
| | | | | Complex GD3 | | (350 Å) |
| | | | | (47:47:6) (400 Å) | | |
| Comparative | Compound | Compound | Compound | Compound | Compound | Compound |
| Example 3 | HI | HT | PH-17 | PH-17:Compound | GH0 | ET:Liq |
| | (100 Å) | (350 Å) | (50 Å) | GH0:Metal | (50 Å) | (40:60) |
| | | | | Complex GD3 | | (350 Å) |
| | | | | (47:47:6) (400 Å) | | |

The new material used in the devices has the following structure:

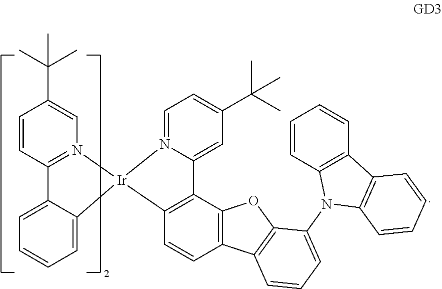

The capacitance of the device was tested using an impedance analyzer (Model No. Keysight E4990A). A direct current bias voltage of −4 V to 5 V was applied to the electrodes at both ends of the device, a sinusoidal alternating current voltage signal of 100 mV was additionally applied, and the capacitance was separately tested at an alternating current voltage with a frequency of 500 Hz. The C-V curve of the device was measured, the initial voltages (Vₜ and Vₜ₀), the voltages (V_{Cmax} and V_{Cmax0}) corresponding to the maximum capacitance, the maximum capacitance (Cₘₐₓ and Cₘₐₓ₀) of the device were obtained, and these data are recorded and shown in Table 7.

TABLE 7
Data in Examples 8 to 10 and Comparative Example 3

| | | Voltage | | |
|---|---|---|---|---|
| | initial | corresponding | Maximum | |
| | voltage | to the maximum | capacitance | Cₘₐₓ − Cₘₐₓ₀ |
| Device ID | [V] | capacitance [V] | [nF] | [nF] |
| Example 8 | −2.56 | 3.47 | 2.44 | −1.31 |
| Example 9 | −1.26 | 2.26 | 2.74 | −1.01 |
| Example 10 | −1.39 | 2.26 | 2.72 | −1.03 |
| Comparative | −3.46 | 2.30 | 3.75 | 0.00 |
| Example 3 | | | | |

As can be seen from the data shown in Table 7, Device Examples 8 to 10 and Comparative Example 3 all use the same metal complex GD3 as the emissive material in the emissive layer, and the metal complex has a ligand Lₐ having a structure represented by Formula 1 of the present application; Device Examples 8 to 10 use Compounds A-9, A-22, and A-19 as the first compound in the emissive layer, respectively, and compared with the maximum capacitance in Device Comparative Example 3 using GH0 as the first compound in the emissive layer, the maximum capacitance in Device Examples 8 to 10 is significantly reduced, by 1.31 nF, 1.01 nF, and 1.03 nF, respectively. The above shows that in the present disclosure, by selecting the combination of the materials (the combination of the first compound and the first metal complex) in the emissive layer of the organic electroluminescent device, the electron and hole balance of the device can be improved, and the capacitance of the device can be reduced, thereby improving the response time and the refresh frequency of the device at low grayscales.

As can be seen from the above results, when the metal complex including the ligand Lₐ having a structure represented by Formula 1 of the present application is used in the emissive layer and the first compound of the present disclosure is also used as the host material in the emissive layer, the capacitance of the device is lower than the capacitance of the device where the widely used GH0 is used as the host material, thereby facilitating the improvement of the response rate of the OLED display device at low grayscales and the improvement of the refreshing frequency of the device. The device disclosed in the present disclosure has huge advantages and broad prospects in industrial applications.

It should be understood that various embodiments described herein are merely examples and not intended to limit the scope of the present disclosure. Therefore, it is apparent to the persons skilled in the art that the present disclosure as claimed may include variations from specific embodiments and preferred embodiments described herein. Many of materials and structures described herein may be substituted with other materials and structures without departing from the spirit of the present disclosure. It should be understood that various theories as to why the present disclosure works are not intended to be limitative.

1. An organic electroluminescent device, comprising a cathode, an anode, and an organic layer disposed between the cathode and the anode;
the organic layer comprises a first emissive layer, and the first emissive layer comprises a first compound and a first metal complex;
the capacitance characteristic of the organic electroluminescent device satisfies the following conditions:
at 500 Hz, a maximum value of a capacitance of the organic electroluminescent device is Cₘₐₓ; and
at 500 Hz, a maximum value of a capacitance of an organic electroluminescent device using compound GH0 to replace the first compound in the first emissive layer is Cₘₐₓ₀; 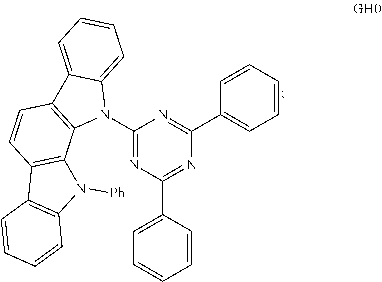 [SMILES: c1ccc(-c2nc(-c3ccccc3)nc(-n3c4ccccc4c4ccc5c6ccccc6n(-c6ccccc6)c5c43)n2)cc1]
wherein Cₘₐₓ−Cₘₐₓ₀≤−0.35 nF;
the first metal complex has a general formula of M(Lₐ)ₘ(L_{b})ₙ(L_{c})_{q};
M is selected from a metal with a relative atomic mass greater than 40;
Lₐ, L_{b}, and L_{c} are a first ligand, a second ligand, and a third ligand coordinated to the metal M, respectively, and Lₐ, L_{b}, and L_{c} are identical or different; wherein Lₐ, L_{b}, and L_{c} can be optionally joined to form a tetradentate ligand or a multidentate ligand;
m is selected from 1, 2 or 3, n is selected from 0, 1 or 2, q is selected from 0, 1 or 2, and m+n+q equals an oxidation state of the metal M; when m is greater than or equal to 2, a plurality of Lₐ are identical or different; when n is equal to 2, two L_{b} are identical or different; when q is equal to 2, two L_{c} are identical or different;
the ligand Lₐ has a structure represented by Formula 1: 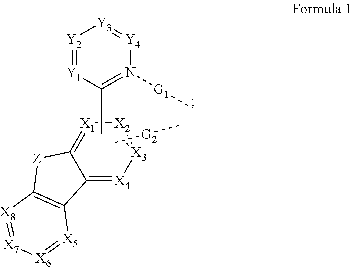
wherein
Z is selected from the group consisting of O, S, Se, NR, CRR, SiRR, and GeRR; when two R are present, the two R are identical or different;
G₁ and G₂ are, at each occurrence identically or differently, selected from a single bond, O or S;
two of X₁ to X₄ are selected from C, one of the two C is joined to the N-containing ring shown in Formula 1, the other one of the two C is joined to the metal via G2, and the remaining two of X₁ to X₄ are each independently selected from CRₓ;
X₅ to X₈ are, at each occurrence identically or differently, selected from CRₓ;
Y₁ to Y₄ are, at each occurrence identically or differently, selected from CR_{y} or N;
R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents R, Rₓ, and R_{y} can be optionally joined to form a ring; and
L_{b} and L_{c} are, at each occurrence identically or differently, selected from a monoanionic multidentate ligand.

2. The organic electroluminescent device of claim 1, wherein a lowest unoccupied molecular orbital energy level E_{LUMO} of the first compound is less than or equal to −2.75 eV; and
preferably, the lowest unoccupied molecular orbital energy level E_{LUMO} of the first compound is less than or equal to −2.80 eV.

3. The organic electroluminescent device of claim 1, wherein at 500 Hz, Cₘₐₓ−Cₘₐₓ₀≤−0.45 nF;
preferably, at 500 Hz, Cₘₐₓ−Cₘₐₓ₀≤−0.55 nF.

4. The organic electroluminescent device of claim 1, wherein at 500 Hz, 2.5 nF≤Cₘₐₓ≤6.0 nF.

5. The organic electroluminescent device of claim 1, wherein at 500 Hz, for the maximum value of the capacitance of the organic electroluminescent device, 0.5 nF≤Cₘₐₓ≤5.5 nF;
preferably, for the maximum value of the capacitance of the organic electroluminescent device, 1.0 nF≤Cₘₐₓ≤4.0 nF; and
more preferably, for the maximum value of the capacitance of the organic electroluminescent device, 1.0 nF≤Cₘₐₓ≤3.0 nF.

6. The organic electroluminescent device of claim 1, wherein at 500 Hz, an initial voltage of the organic electroluminescent device is V t and satisfies: −4.0 V≤Vₜ≤5.0 V; and
preferably, at 500 Hz, the initial voltage of the organic electroluminescent device is V t and satisfies: −3.0 V≤Vₜ≤3.0 V.

7. The organic electroluminescent device of claim 1, wherein at 500 Hz, when the capacitance of the organic electroluminescent device reaches the maximum value Cₘₐₓ, a corresponding voltage is V_{Cmax} and satisfies: 1.0 V≤V_{Cmax}≤6.0 V; and
preferably, at 500 Hz, when the capacitance of the organic electroluminescent device reaches the maximum value Cₘₐₓ, the corresponding voltage is V_{Cmax} and satisfies: 1.5 V≤V_{Cmax}≤5.0 V.

8. The organic electroluminescent device of claim 1, wherein the first emissive layer further comprises a second compound;
the second compound comprises at least one chemical group selected from the group consisting of: benzene, pyridine, pyrimidine, triazine, carbazole, azacarbazole, indolocarbazole, dibenzothiophene, azadibenzothiophene, dibenzofuran, azadibenzofuran, dibenzoselenophene, triphenylene, azatriphenylene, fluorene, silafluorene, naphthalene, quinoline, isoquinoline, quinazoline, quinoxaline, phenanthrene, azaphenanthrene, and combinations thereof; and
preferably, the second compound comprises at least one chemical group selected from the group consisting of: benzene, carbazole, indolocarbazole, fluorene, silafluorene, and combinations thereof.

9. The organic electroluminescent device of claim 8, wherein the first metal complex is doped in the first compound and the second compound, and a weight of the first metal complex accounts for 1% to 30% of a total weight of the first emissive layer; and
preferably, the first metal complex is doped in the first compound and the second compound, and the weight of the first metal complex accounts for 3% to 13% of the total weight of the first emissive layer.

10. The organic electroluminescent device of claim 1, wherein the first compound has a structure as show in Formula 2: 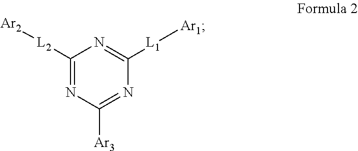
wherein
L₁ and L₂ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms or combinations thereof;
Ar₁ and Ar₂ are, at each occurrence identically or differently, selected from substituted or unsubstituted aryl having 6 to 30 carbon atoms, substituted or unsubstituted heteroaryl having 3 to 30 carbon atoms or combinations thereof;
Ar₃ has a structure represented by Formula A: 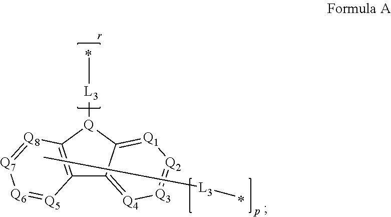
wherein
Q is, at each occurrence identically or differently, selected from the group consisting of O, S, Se, N, NR_{Q}, CR_{Q}R_{Q}, SiR_{Q}R_{Q}, GeR_{Q}R_{Q}, R_{Q}C═CR_{Q}, and C═CR_{Q}; when two R_{Q} are present, the two R_{Q} can be identical or different;
L₃ is, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 20 carbon atoms, substituted or unsubstituted heteroarylene having 3 to 20 carbon atoms or combinations thereof;
p is 0 or 1, r is 0 or 1, and p+q=1;
when p is 0 and r is 1, Q is selected from N or C═CR_{Q}; Q₁ to Q₈ are, at each occurrence identically or differently, selected from CR_{q} or N; when Q is selected from N and L₃ is a single bond, adjacent substituents R_{q} cannot be joined to form an indole ring or a benzoindole ring; when Q is selected from C═CR_{Q}, the C which is not directly joined to R_{Q} is joined to L₃ in Formula A;
when p is 1 and r is 0, Q is selected from the group consisting of O, S, Se, NR_{Q}, CR_{Q}R_{Q}, SiR_{Q}R_{Q}, GeR_{Q}R_{Q}, and R_{Q}C═CR_{Q}; Q₁ to Q₈ are, at each occurrence identically or differently, selected from C, CR q or N; one of Q₁ to Q₈ is selected from C, and the C is joined to L₃ in Formula A;
R_{Q} and R_{q} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
“*” represents a position where Formula A is joined to Formula 2; and
adjacent substituents R_{Q} and R_{q} can be optionally joined to form a ring.

11. The organic electroluminescent device of claim 1, wherein the first compound has a structure represented by Formula 2-1 or Formula 2-2: 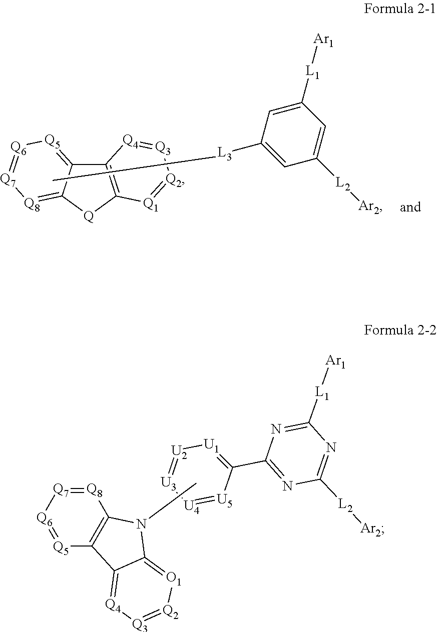
wherein
Q is, at each occurrence identically or differently, selected from the group consisting of O, S, and Se;
in Formula 2-1, Q₁ to Q₈ are, at each occurrence identically or differently, selected from C, CR_{q} or N, and one of Q₁ to Q₈ is C and is joined to L₃;
in Formula 2-2, Q₁ to Q₈ are, at each occurrence identically or differently, selected from CR_{q} or N;
U₁ to U₅ are, at each occurrence identically or differently, selected from C, CRᵤ or N, and one of U₁ to U₅ is C and is joined to a structure 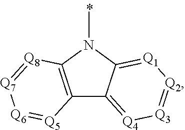
wherein “*” represents a joining position;
L₁ to L₃ are, at each occurrence identically or differently, selected from a single bond, substituted or unsubstituted alkylene having 1 to 20 carbon atoms, substituted or unsubstituted cycloalkylene having 3 to 20 carbon atoms, substituted or unsubstituted arylene having 6 to 30 carbon atoms, substituted or unsubstituted heteroarylene having 3 to 30 carbon atoms or combinations thereof;
Ar₁ and Ar₂ are, at each occurrence identically or differently, selected from substituted or unsubstituted aryl having 6 to 30 carbon atoms, substituted or unsubstituted heteroaryl having 3 to 30 carbon atoms or combinations thereof;
R_{q} and Rᵤ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof; and
adjacent substituents R_{q} can be optionally joined to form a ring.

12. The organic electroluminescent device of claim 11, wherein the first compound has a structure represented by Formula 2-1, at least one of Q₁ to Q₈ is CR_{q}, and the R_{q} is selected from substituted or unsubstituted aryl having 6 to 30 carbon atoms, substituted or unsubstituted heteroaryl having 3 to 30 carbon atoms or combinations thereof; and
preferably, Q₄ is selected from C and is joined to L₃; Q₈ is CR_{q}, and the R_{q} is substituted or unsubstituted aryl having 6 to 30 carbon atoms; or
Q₂ is selected from C and is joined to L₃; Q₅ is CR_{q}, and the _{q} is substituted or unsubstituted aryl having 6 to 30 carbon atoms.

13. The organic electroluminescent device of claim 11, wherein the first compound has a structure represented by Formula 2-1, wherein Ar₁ and/or Ar₂ have a structure represented by Formula B: 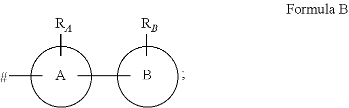
wherein the ring A and the ring B are, at each occurrence identically or differently, selected from an aromatic ring having 6 to 30 carbon atoms, a heteroaromatic ring having 3 to 30 carbon atoms or combinations thereof;
R_{A} and R_{B} represent, at each occurrence identically or differently, mono-substitution, multiple substitutions or non-substitution;
R_{A} and R_{B} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
at least one of R_{A} and R_{B} is selected from a cyano group; preferably, at least one R_{B} is selected from a cyano group;
adjacent substituents R_{A} and R_{B} can be optionally joined to form a ring; and
“#” represents a position where Formula B is joined to Formula 2-1.

14. The organic electroluminescent device of claim 11, wherein the first compound has a structure represented by Formula 2-2, at least one of U₁ to U₅ is CRᵤ, and Rᵤ is selected from substituted or unsubstituted aryl having 6 to 30 carbon atoms, substituted or unsubstituted heteroaryl having 3 to 30 carbon atoms or combinations thereof;
preferably, at least one of U₁ to U₅ is selected from CRᵤ, and Rᵤ is selected from substituted or unsubstituted aryl having 6 to 20 carbon atoms, substituted or unsubstituted heteroaryl having 3 to 20 carbon atoms or combinations thereof; and
more preferably, U₃ is selected from CRᵤ, and Rᵤ is selected from substituted or unsubstituted phenyl, substituted or unsubstituted naphthyl, substituted or unsubstituted phenanthryl, substituted or unsubstituted biphenyl, substituted or unsubstituted terphenyl, substituted or unsubstituted triphenylenyl substituted or unsubstituted fluorenyl, substituted or unsubstituted carbazolyl, substituted or unsubstituted dibenzofuryl, substituted or unsubstituted dibenzothienyl or combinations thereof.

15. The organic electroluminescent device of claim 1, wherein the first compound is selected from the group consisting of the following compounds: 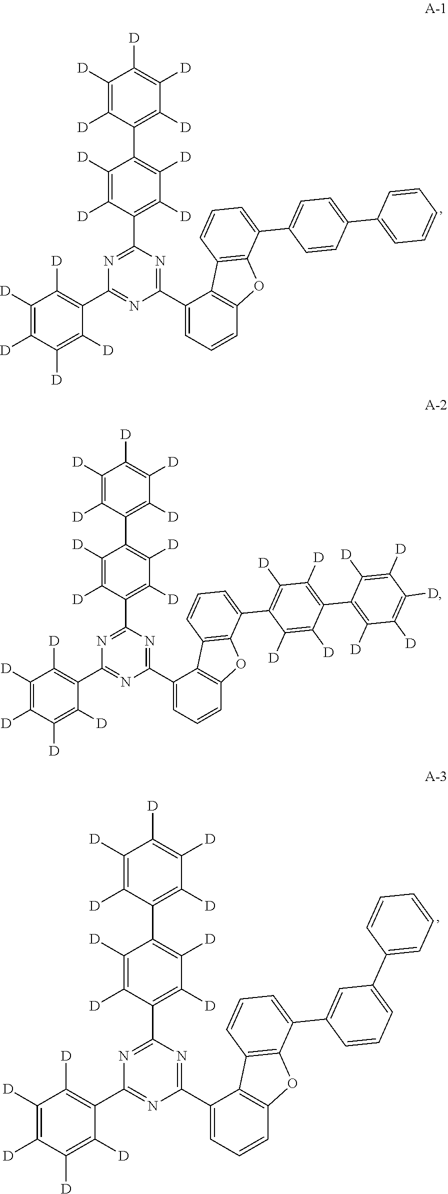 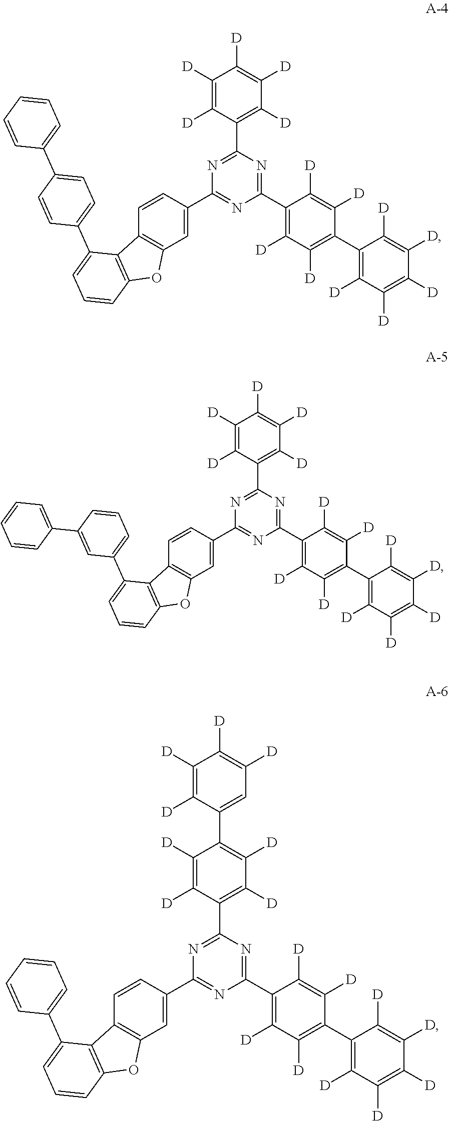 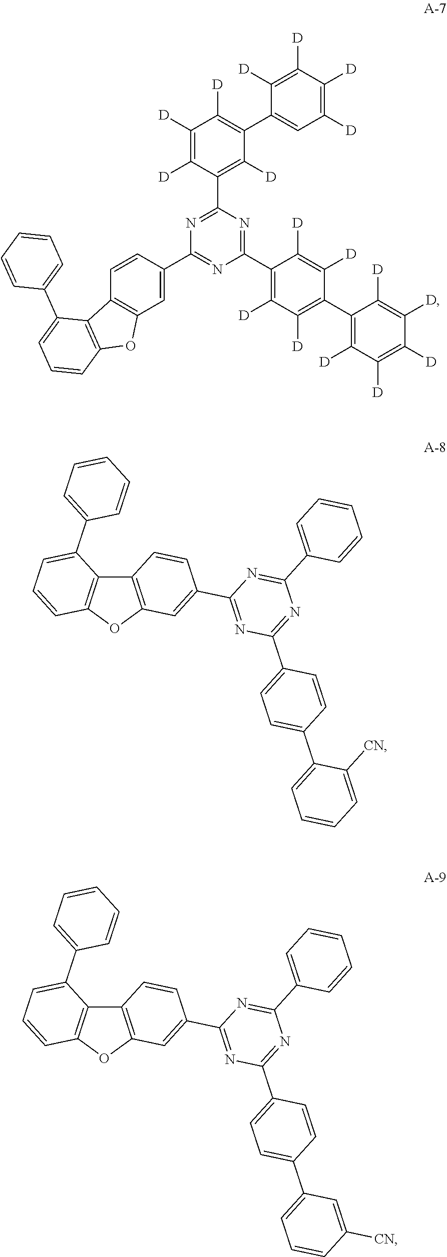 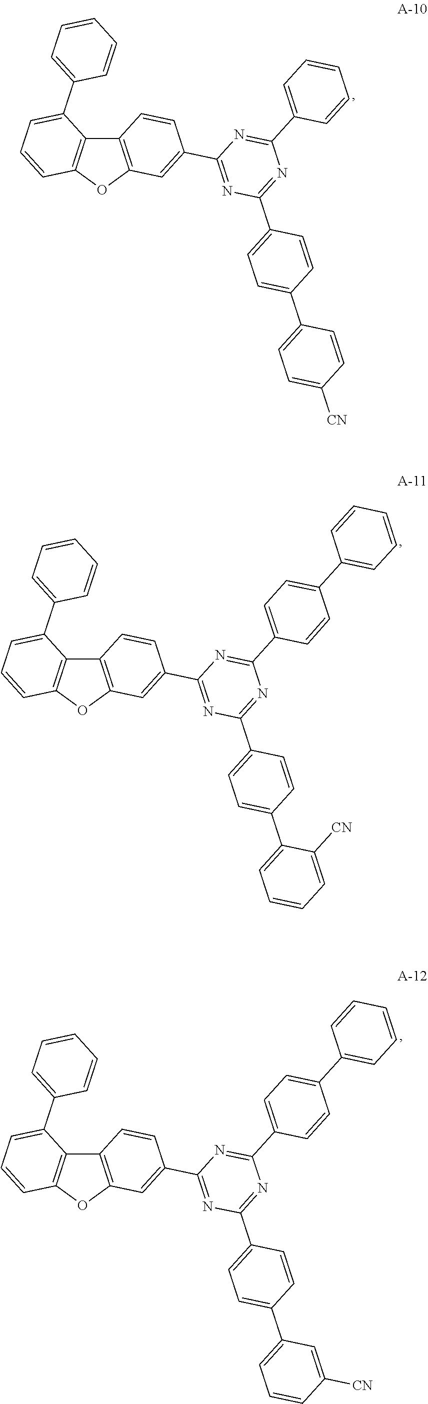 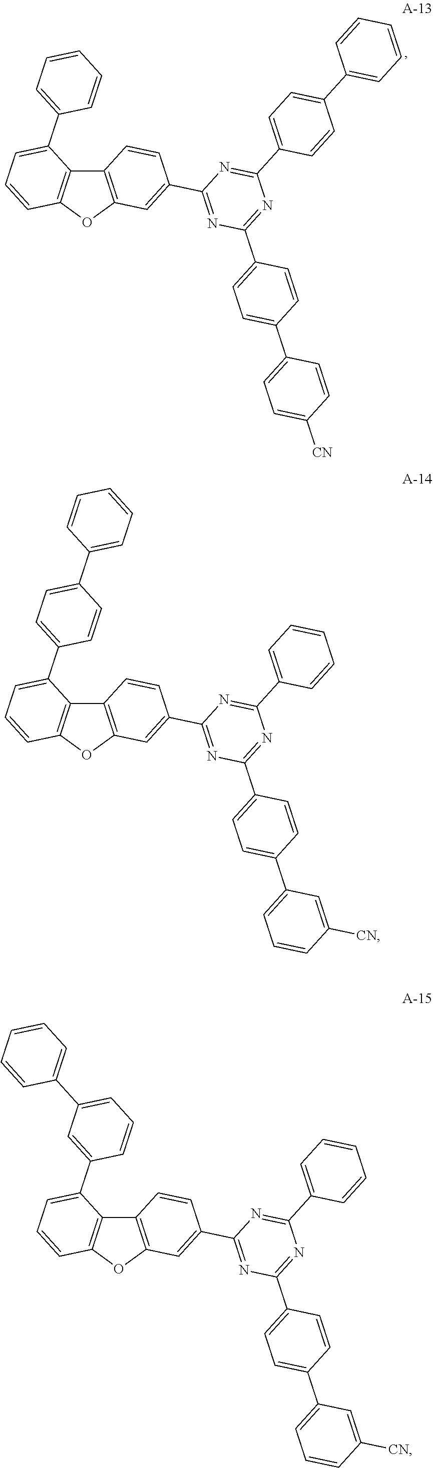 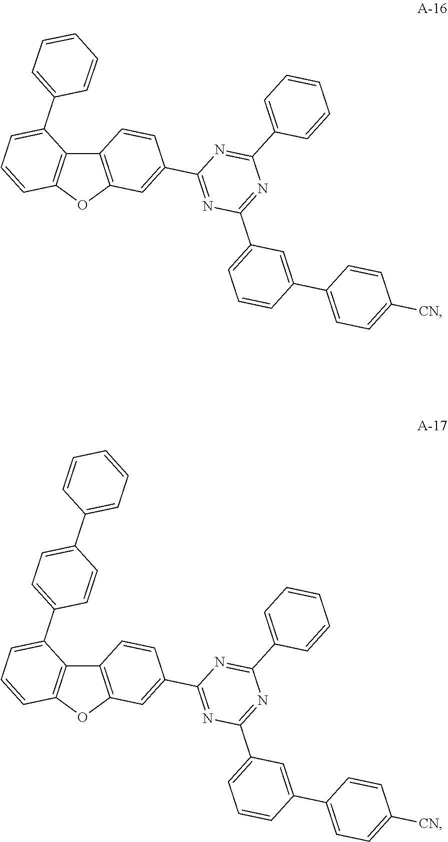 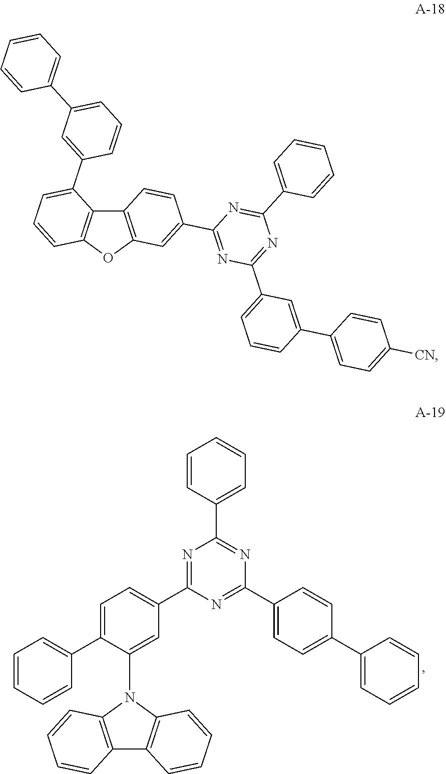 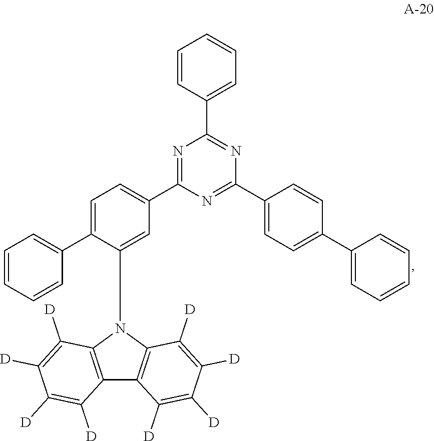 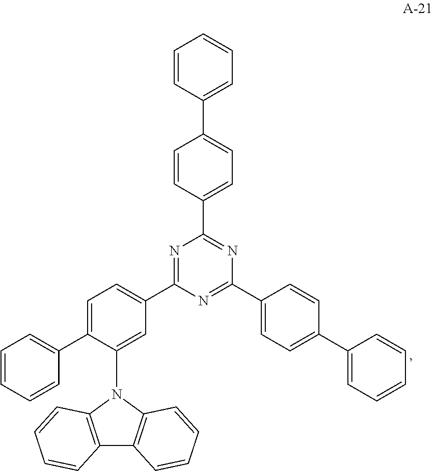 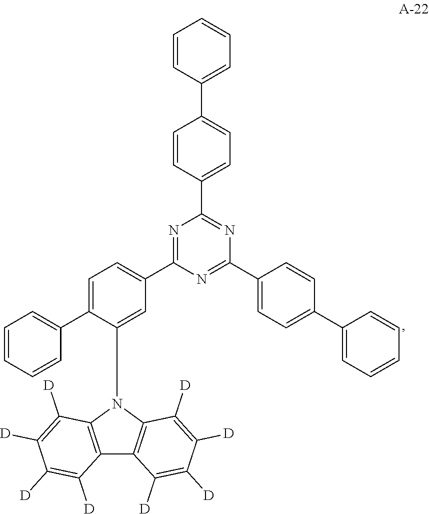 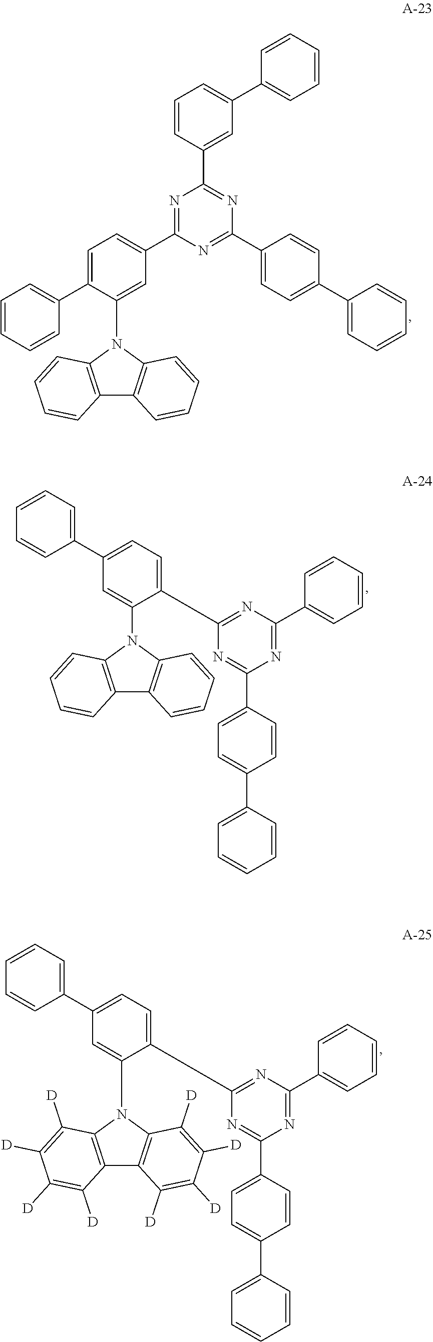 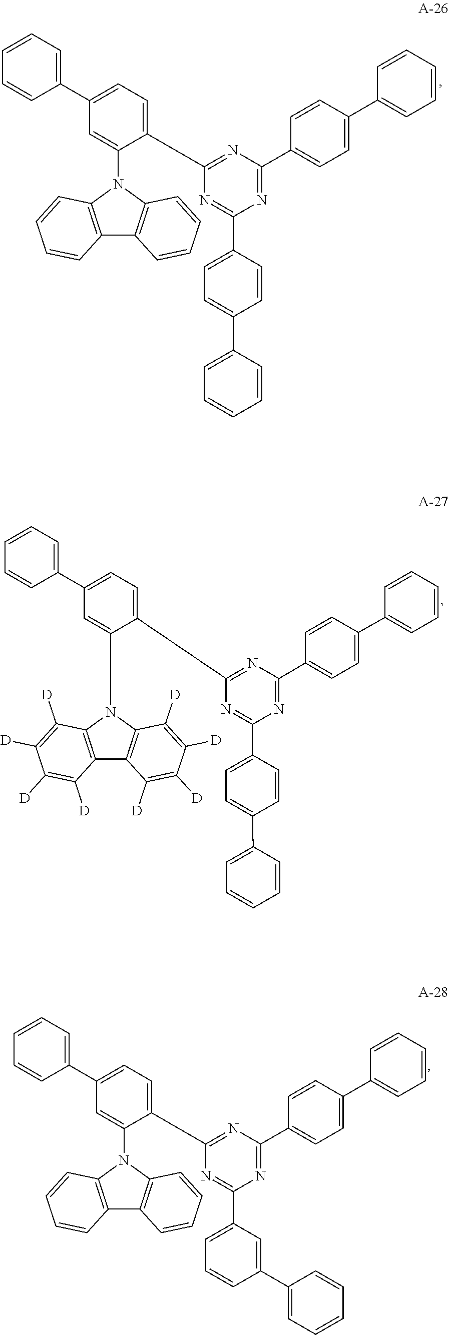 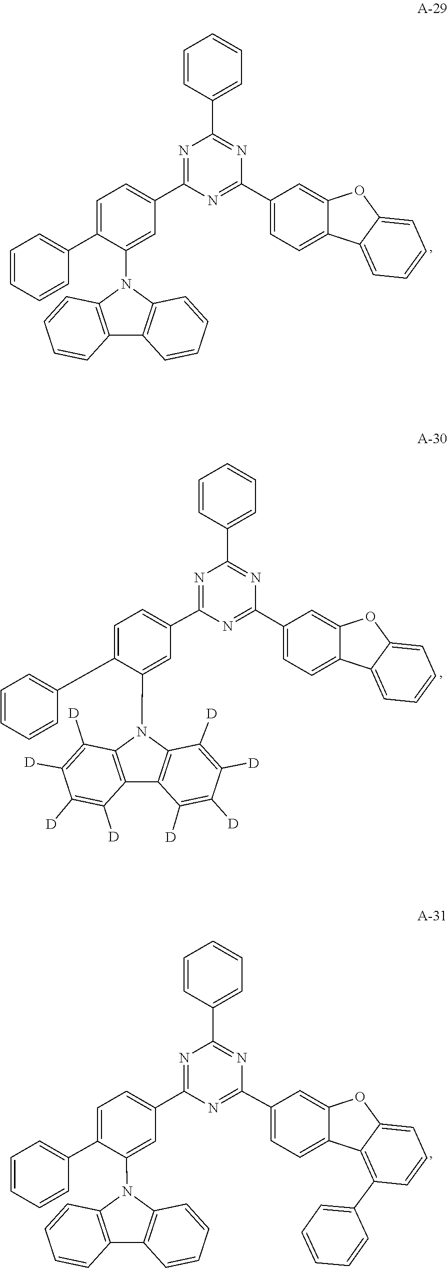 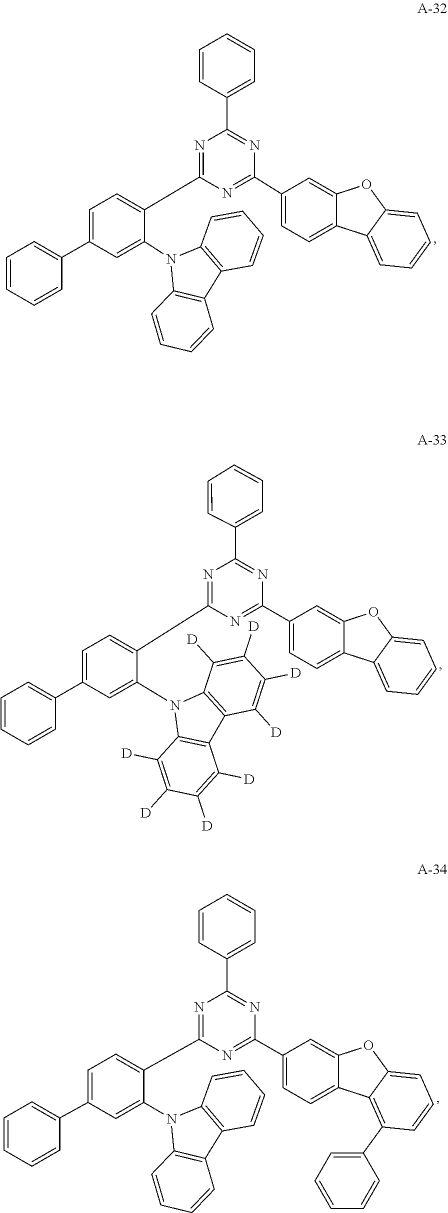 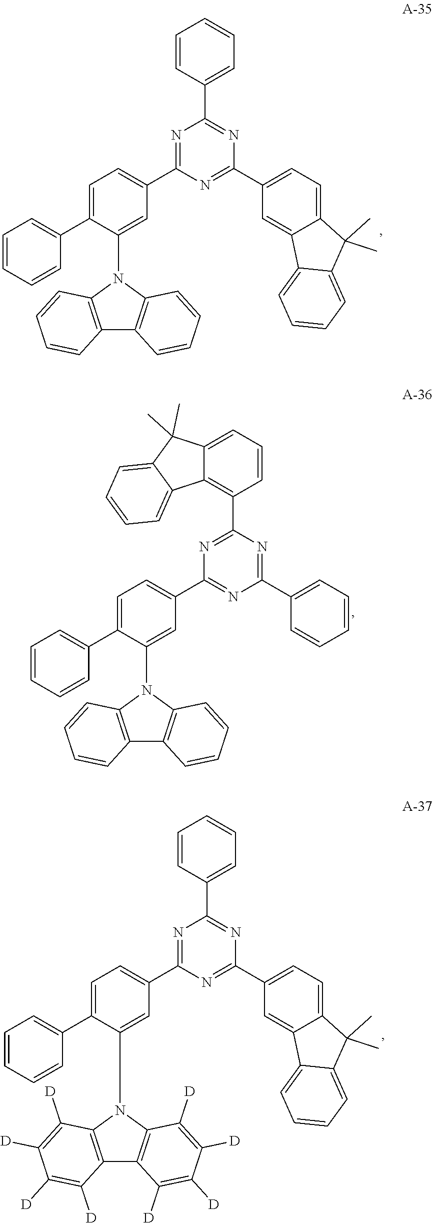 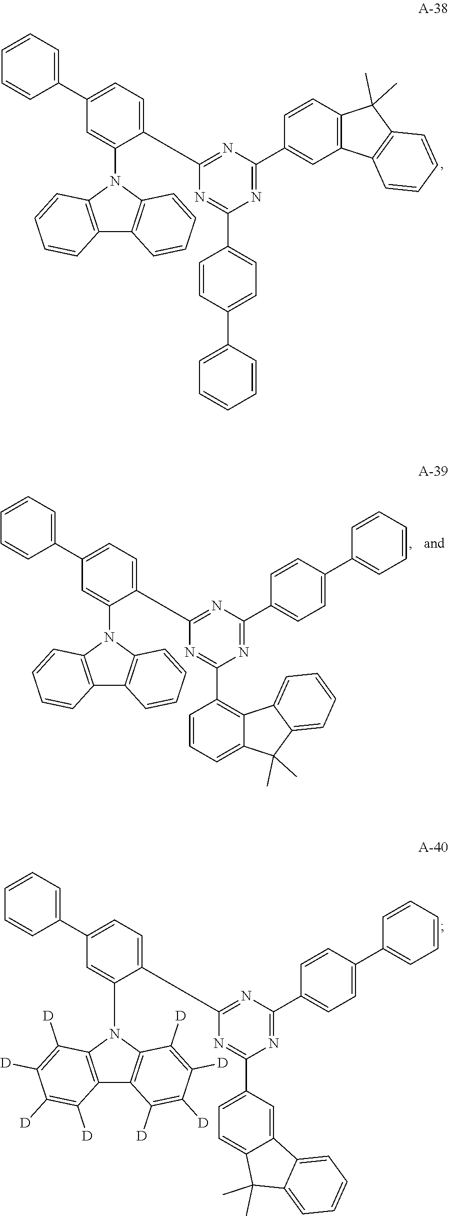
wherein, optionally, hydrogens in Compound A-1 to Compound A-40 can be partially or fully substituted with deuterium.

16. The organic electroluminescence device of claim 1, wherein the metal M is, at each occurrence identically or differently, selected from the group consisting of Cu, Ag, Au, Ru, Rh, Pd, Os, Ir, and Pt; and
preferably, the metal M is, at each occurrence identically or differently, selected from Pt or Ir.

17. The organic electroluminescent device of claim 1, wherein the first metal complex has a structure represented by Formula 3: 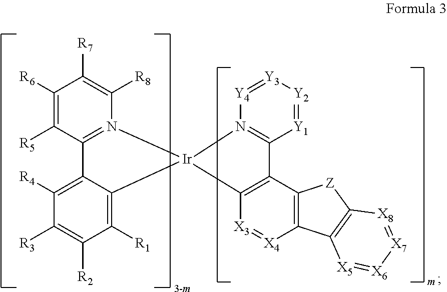
wherein
m is selected from 1, 2 or 3; preferably, m is selected from 1 or 2;
Z is selected from the group consisting of O, S, Se, NR, CRR, SiRR, and GeRR; when two R are present, the two R are identical or different;
X₃ to X₈ are, at each occurrence identically or differently, selected from CRₓ;
Y₁ to Y₄ are, at each occurrence identically or differently, selected from CR_{y} or N;
R₁ to R₈, R, Rₓ, and R_{y} are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
adjacent substituents in R₁ to R₈ can be optionally joined to form a ring; and
adjacent substituents R, Rₓ, and R_{y} can be optionally joined to form a ring.

18. The organic electroluminescent device of claim 17, wherein at least one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclyl having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof;
preferably, at least two of X₃ to X₈ are CRₓ, one Rₓ is a cyano group or fluorine, and at least another one Rₓ is selected from the group consisting of: deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, a cyano group, and combinations thereof; and
more preferably, at least two of X₅ to X₈ are CRₓ, one Rₓ is a cyano group or fluorine, and at least another one Rx is selected from the group consisting of: deuterium, halogen, substituted or unsubstituted alkyl having 1 to 6 carbon atoms, substituted or unsubstituted cycloalkyl having 3 to 6 ring carbon atoms, substituted or unsubstituted aryl having 6 to 12 carbon atoms, substituted or unsubstituted heteroaryl having 3 to 12 carbon atoms, and combinations thereof.

19. The organic electroluminescent device of claim 17, wherein at least one of R₁ to R₈ is selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof;
preferably, at least one of R₅ to R₈ is selected from the group consisting of: deuterium, substituted or unsubstituted alkyl having 1 to 20 carbon atoms, substituted or unsubstituted cycloalkyl having 3 to 20 ring carbon atoms, substituted or unsubstituted aryl having 6 to 30 carbon atoms, substituted or unsubstituted heteroaryl having 3 to 30 carbon atoms, and combinations thereof; and
more preferably, at least one of R₅ to R₈ is selected from the group consisting of: deuterium, substituted or unsubstituted alkyl having 1 to 20 carbon atoms, substituted or unsubstituted cycloalkyl having 3 to 20 ring carbon atoms, and combinations thereof.

20. The organic electroluminescent device of claim 1, wherein the first metal complex is, at each occurrence identically or differently, selected from the group consisting of the following: 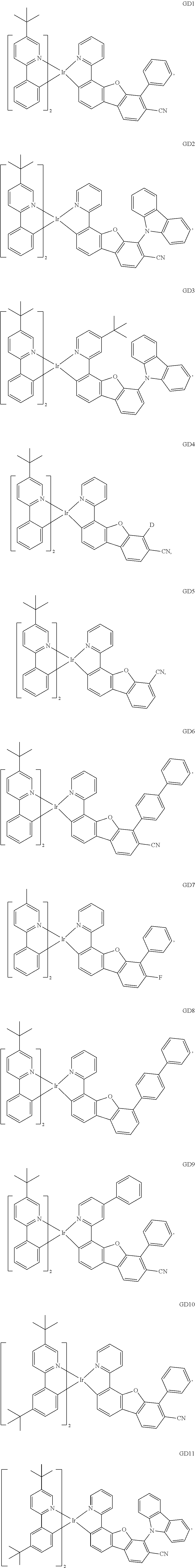 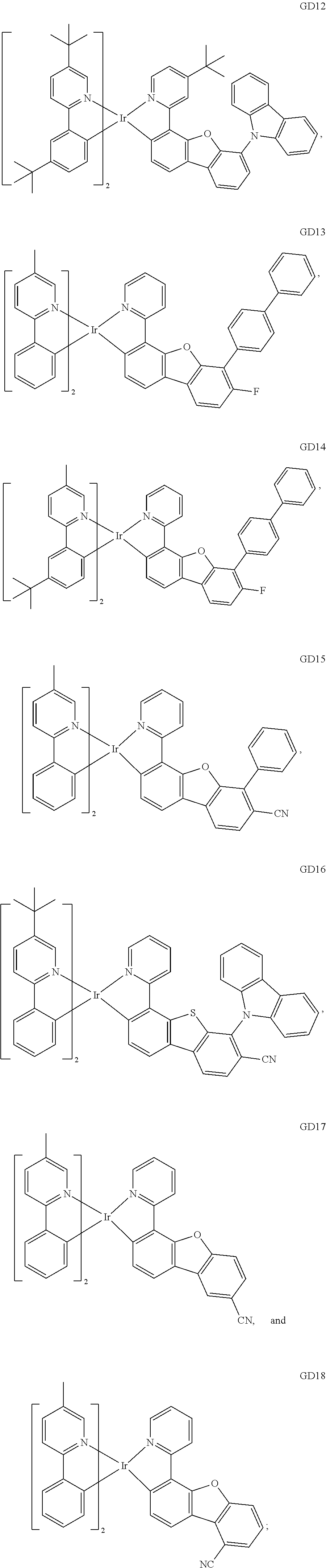
wherein, optionally, hydrogens in Metal Complex GD1 to Metal Complex GD18 can be partially or fully substituted with deuterium.

21. A display assembly, comprising the organic electroluminescent device of claim 1.
